(19) United States
(12) Patent Application Publication
(10) Pub. No.: US 2023/0193067 A1
(43) Pub. Date: Jun. 22, 2023

(54) METAL OXIDE COMPOSITION, LIGHT-EMITTING DEVICE USING THE SAME, AND ELECTRONIC APPARATUS INCLUDING THE LIGHT-EMITTING DEVICE

(71) Applicant: Samsung Display Co., Ltd., Yongin-si, Gyeonggi-do (KR)

(72) Inventors: Sehun Kim, Yongin-s (KR); Sanghee Yu, Yongin-si (KR); Gyubong Kim, Yongin-si (KR); Hoilim Kim, Yongin-si (KR); Jongwoo Shin, Yongin-s (KR); Sangyeop Lee, Yongin-si (KR); Jaekook Ha, Yongin-si (KR); Wonjun Park, Yongin-si (KR); Eunho Song, Yongin-si (KR); Seihwan Ahn, Yongin-si (KR); Dongsun Yoo, Yongin-si (KR)

(21) Appl. No.: 18/067,098

(22) Filed: Dec. 16, 2022

(30) Foreign Application Priority Data
Dec. 17, 2021 (KR) 10-2021-0182205

(51) Int. Cl. C09D 11/52; C09D 11/037; C09D 11/033; C09K 11/70; C09K 11/08; H10K 50/16; H10K 50/858; H10K 50/18; H10K 50/17

(52) U.S. Cl. CPC C09D 11/52; C09D 11/033; C09D 11/037; C09K 11/70; C09K 11/0883; H10K 50/16; H10K 50/18; H10K 50/171; H10K 50/858; B82Y 20/00

(57) ABSTRACT

A metal oxide composition, including: a solvent; and a metal oxide, wherein the solvent includes a first compound represented by Formula 1, and the metal oxide includes a second compound represented by Formula 2

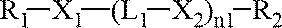

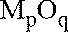

wherein, X₁ and X₂ are each independently *—B(R₁ₐ)—*’, *—N(R₁ₐ)—*’, *—O—*’, *—P(R₁ₐ)—*’, *—P(═O)(R₁ₐ)—*’, *—S—*, *—S(═O)—*’, *—S(═O)₂—*’, or *—Si(R₁ₐ)(R_{1b})—*’; * and *’ each indicate a binding site to a neighboring atom; R₁ is hydrogen or deuterium; M is Zn, Ti, Zr, Sn, W, Ta, Ni, Mo, Cu, or V; p and q are each independently from 1 to 5; and the other substituents are respectively as described in the present specification.

### CROSS-REFERENCE TO RELATED APPLICATION

This application is based on and claims priority to Korean Patent Application No. 10-2021-0182205, filed on Dec. 17, 2021, in the Korean Intellectual Property Office, and all the benefits accruing therefrom under 35 U.S.C. §119, the content of which is incorporated by reference herein in its entirety.

### BACKGROUND

### 1. Field

One or more embodiments relate to a metal oxide composition, a light-emitting device using the same, and an electronic apparatus including the light-emitting device.

### 2. Description of the Related Art

Light-emitting devices (LEDs) are devices that convert electrical energy into light energy. Examples of such light-emitting devices include organic light-emitting devices (OLEDs) in which a light-emitting material is an organic material, and quantum dot light-emitting devices in which the light-emitting material is a quantum dot.

In a light-emitting device, a first electrode is arranged on a substrate, and a hole transport region, an emission layer, an electron transport region, and a second electrode are sequentially arranged on the first electrode. Holes provided from the first electrode may move toward the emission layer through the hole transport region, and electrons provided from the second electrode may move toward the emission layer through the electron transport region. Carriers, such as holes and electrons, recombine in such an emission layer region to produce excitons. These excitons transition from an excited state to a ground state to thereby generate light.

### SUMMARY

Provided are a metal oxide composition, a light-emitting device using the same, and an electronic apparatus including the light-emitting device.

Additional aspects will be set forth in part in the description which follows and, in part, will be apparent from the description, or may be learned by practice of the presented embodiments.

According to an aspect, provided is a metal oxide composition including a solvent, and a metal oxide, wherein the solvent includes a first compound represented by Formula 1, and the metal oxide includes a second compound represented by Formula 2:

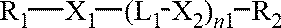

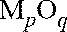

### In Formulae 1 and 2

L₁ is a single bond, a C₁-C₆₀ alkylene group that is unsubstituted or substituted with at least one R₁₀ₐ, a C₂-C₆₀ alkenylene group that is unsubstituted or substituted with at least one R₁₀ₐ, a C₂-C₆₀ alkynylene group that is unsubstituted or substituted with at least one R₁₀ₐ, a C₃-C₆₀ carbocyclic group that is unsubstituted or substituted with at least one R₁₀ₐ, a C1-C₆₀ heterocyclic group that is unsubstituted or substituted with at least one R₁₀ₐ, or a combination thereof,
n1 is an integer from 1 to 10,
X₁ and X₂ are each independently *—B(R₁ₐ)—*’, *—N(R₁ₐ)—*’, *—O—*’, *—P(R₁ₐ)—*’, *—P(═O)(R₁ₐ)—*’, *—S—*’, *—S(═O)—*’, *—S(═O)₂—*’, or *—Si(R₁ₐ)(R_{1b})—*’,
* and *’ each indicate a binding site to a neighboring atom,
R₁ is hydrogen or deuterium,
R₂ is a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, or a C₁-C₆₀ heteroarylthio group that is unsubstituted or substituted with at least one R₁₀ₐ,
R₁ₐ and R_{1b} are each independently hydrogen, deuterium, —F, —CI, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), —P(Q₁)(Q₂) or —P(═O)(Q₁)(Q₂),
M is Zn, Ti, Zr, Sn, W, Ta, Ni, Mo, Cu, or V,
p and q are each independently an integer from 1 or 5,
R₁₀ₐ is:
   deuterium, —F, —CI, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, or a phosphoric acid group or a salt thereof,
   a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each unsubstituted or substituted with at least one of deuterium, —F, —CI, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group,—Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof,
   a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, each unsubstituted or substituted with at least one of deuterium, —F, —CI, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group, a C₆-C₆₀ arylthio group, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof, or
   —Si(Q₃i)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
   Q₁ to Q₃, Q₁₁ to Q₁₃, Q₂₁ to Q₂₃, and Q₃₁ to Q₃₃ are each independently hydrogen, deuterium, —F, —CI, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₆₀ carbocyclic group, a substituted or unsubstituted C₁-C₆₀ heterocyclic group, a C₇-C₆₀ alkyl aryl group, a substituted or unsubstituted C₇-C₆₀ aryl alkyl group, a substituted or unsubstituted C₆-C₆₀ arylthio group, a substituted or unsubstituted C₁-C₆₀ alkyl heteroaryl group, a substituted or unsubstituted C₂-C₆₀ heteroaryl alkyl group, a substituted or unsubstituted C₁-C₆₀ heteroaryloxy group, or a substituted or unsubstituted C₁-C₆₀ heteroarylthio group, and
   the first compound satisfies at least one of Condition 1 or Condition 2:
      Condition 1 At least one of n1 L₁(s) is substituted with at least one R₁₀ₐ
      Condition 2 R₂ is substituted with at least one R₁₀ₐ.

According to another aspect, provided is a light-emitting device including a first electrode, a second electrode facing the first electrode, an interlayer arranged between the first electrode and the second electrode, and a metal oxide layer formed by using the metal oxide composition.

According to still another aspect, provided is an electronic apparatus including the light-emitting device.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic view of a structure of a light-emitting device according to one or more embodiments;

FIG. 2 is a schematic view of a structure of an electronic apparatus according to one or more embodiments; and

FIG. 3 is a schematic view of a structure of an electronic apparatus according to another embodiment.

### DETAILED DESCRIPTION

Reference will now be made in further detail to exemplary embodiments, examples of which are illustrated in the accompanying drawings, wherein like reference numerals refer to like elements throughout. In this regard, the present exemplary embodiments may have different forms and should not be construed as being limited to the descriptions set forth herein. Accordingly, the exemplary embodiments are merely described below, by referring to the figures, to explain particular aspects of the present detailed description.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. As used herein, the term “and/or” includes any and all combinations of one or more of the associated listed items. Throughout the application, the expression “at least one of a, b or c” indicates only a, only b, only c, both a and b, both a and c, both b and c, all of a, b, and c, or variations thereof. The term “or” means “and/or.”

The disclosed subject matter may include various modifications and various embodiments, and specific embodiments will be illustrated in the drawings and described in detail in the detailed description. Effects and features of the subject matter, and implementation methods therefor will become clear with reference to the exemplary embodiments described later together with the drawings. The present subject matter may, however, be embodied in many different forms and should not be construed as limited to the embodiments set forth herein.

It will be understood that, although the terms first, second, etc. may be used herein to describe various elements, these elements should not be limited by these terms. These terms are only used to distinguish one element from another. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

In the embodiments described in the present specification, an expression used in the singular encompasses the expression of the plural, unless it has a clearly different meaning in the context.

In the present specification, it is to be understood that the terms such as “including,” “having,” and “comprising” are intended to indicate the existence of the features or components disclosed in the specification and are not intended to preclude the possibility that one or more other features or components may exist or may be added. For example, unless otherwise limited, terms such as “including” or “having” may refer to either consisting of features or components described in the specification only or further including other components.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ± 30%, 20%, 10%, 5% of the stated value.

Hereinafter, a work function or a highest occupied molecular orbital (HOMO) energy level is expressed as an absolute value from a vacuum level. In addition, when the work function or the HOMO energy level is referred to be “deep,” “high” or “large,” the work function or the HOMO energy level has a large absolute value based on “0 eV” of the vacuum level, while when the work function or the HOMO energy level is referred to be “shallow,” “low,” or “small,” the work function or HOMO energy level has a small absolute value based on “0 eV” of the vacuum level.

The term “Group II” used herein may include a Group IIA element and a Group IIB element on the IUPAC Periodic Table of Elements, and examples of the Group II element may include Cd, Mg, and Zn, but embodiments are not limited thereto.

The term “Group III” used herein may include a Group IIIA element and a Group IIIB element on the IUPAC Periodic Table of Elements, and examples of the Group III element may include Al, In, Ga, and TI, but embodiments are not limited thereto.

The term “Group IV” used herein may include a Group IVA element and a Group IVB element on the IUPAC Periodic Table of Elements, and examples of the Group IV element may include Si, Ge, and Sn, but embodiments are not limited thereto.

The term “Group V” used herein may include a Group VA element on the IUPAC Periodic Table of Elements, and examples of the Group V element may include N, P, As, Sb, and Bi, but embodiments are not limited thereto.

The term “Group VI” used herein may include a Group VIA element in the IUPAC Periodic Table of Elements, and examples of the Group VI element may include O, S, Se, and Te, but embodiments are not limited thereto.

The term “metal” used herein may include metalloid such as Si. Examples of the metalloid may include B, Si, Ge, As, Sb, Te, and the like.

Hereinafter, a metal oxide composition according to one or more exemplary embodiments may be described.

### Metal Oxide Composition

The metal oxide composition includes a solvent; and a metal oxide, wherein the solvent includes a first compound represented by Formula 1, and the metal oxide includes a second compound represented by Formula 2.

First compound

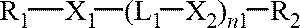

L₁ in Formula 1 is a single bond, a C₁-C₆₀ alkylene group that is unsubstituted or substituted with at least one R₁₀ₐ, a C₂-C₆₀ alkenylene group that is unsubstituted or substituted with at least one R₁₀ₐ, a C₂-C₆₀ alkynylene group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, or a combination thereof, and R₁₀ₐ may be as described herein.

In one or more embodiments, L₁ may be a C₁-C₆₀ alkylene group that is unsubstituted or substituted with at least one R₁₀ₐ, a C₃-C₁₀ cycloalkylene group that is unsubstituted or substituted with at least one R₁₀ₐ, a C₃-C₁₀ heterocycloalkenylene group that is unsubstituted or substituted with at least one R₁₀ₐ, a C₃-C₁₀ cycloalkenylene group that is unsubstituted or substituted with at least one R₁₀ₐ, or a C₁-C₁₀ heterocycloalkenylene group that is unsubstituted or substituted with at least one R₁₀ₐ.

In one or more embodiments, L₁ may be a C₁-C₁₀ alkylene group that is unsubstituted or substituted with at least one R₁₀ₐ,

R₁₀ₐ is:
a C₁-C₆₀ alkyl group, a C₂-C₆₀ alkenyl group, a C₂-C₆₀ alkynyl group, a C₁-C₆₀ alkoxy group, a C₁-C₆₀ alkylthio group, each unsubstituted or substituted with at least one of deuterium, a hydroxyl group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), or a combination thereof; or
a C₃-C₆₀ carbocyclic group or a C₁-C₆₀ heterocyclic group, each unsubstituted or substituted with deuterium, a hydroxyl group, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), or a combination thereof, and
Q₁₁ to Q₁₃ and Q₂₁ to Q₂₃ are respectively as described herein.

n1 in Formula 1 is an integer from 1 to 10.

In one or more embodiments, n1 in Formula 1 may be an integer from 1 to 5.

When n1 is greater than 1, each L₁ may be identical to or different from each other. For example, one L₁ among a plurality of L₁ may be substituted with at least one R₁₀ₐ, and (n1-1) L₁ may not have a substituent.

X₁ and X₂ in Formula 1 are each independently *—B(R₁ₐ)—*’, *—N(R₁ₐ)—*’, *—O—*’, *—P(R₁ₐ)—*’, *—P(═O)(R₁ₐ)—*’, *—S—*’, *—S(═O)—*’, *—S(═O)₂—*’, or *—Si(R₁ₐ)(R_{1b})—*’, and * and *’ each indicate a binding site to a neighboring atom.

In one or more embodiments, X₁ and X₂ may each independently be *—N(R₁ₐ)—*’, *—O—*’, *—S—’, or *—Si(R₁ₐ)(R_{1b})—*’.

R₁ₐ and R_{1b} are each independently hydrogen, deuterium, —F, —CI, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and R₁₀ₐ and Q₁ to Q₃ are respectively as described herein.

In one or more embodiments, R₁ₐ and R_{1b} may each independently be:
hydrogen, deuterium, —F, —CI, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with at least one of deuterium, —F, —CI, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a pyrrolidinyl group, a piperidinyl group, a phenyl group, a biphenyl group, a naphthyl group, a pyridinyl group, a pyrimidinyl group, or a combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a pyrrolidinyl group, a piperidinyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with at least one of deuterium, —F, —CI, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a pyrrolidinyl group, a piperidinyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═Q)(Q₃₁)(Q₃₂), or a combination thereof; or
—Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ may each independently be:
   —CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
   an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with at least one of deuterium, a C₁-C₁₀ alkyl group, a phenyl group, a biphenyl group, a pyridinyl group, a pyrimidinyl group, a pyridazinyl group, a pyrazinyl group, a triazinyl group, or a combination thereof.

R₁ in Formula 1 is hydrogen or deuterium.

R₂ in Formula 1 is a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C1-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, or a C₁-C₆₀ heteroarylthio group that is unsubstituted or substituted with at least one R₁₀ₐ

In one or more embodiments, R₂ may be:
a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with at least one of deuterium, —F, —CI, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a pyrrolidinyl group, a piperidinyl group, a phenyl group, a biphenyl group, a naphthyl group, a pyridinyl group, a pyrimidinyl group, or a combination thereof; or
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a pyrrolidinyl group, a piperidinyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with at least one of deuterium, —F, —CI, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a pyrrolidinyl group, a piperidinyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or a combination thereof, and
   Q₁ to Q₃ and Q₃₁ to Q₃₃ may each independently be:
      —CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
      an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with at least one of deuterium, a C₁-C₁₀ alkyl group, a phenyl group, a biphenyl group, a pyridinyl group, a pyrimidinyl group, a pyridazinyl group, a pyrazinyl group, a triazinyl group, or a combination thereof.

The first compound satisfies at least one of Condition 1 or Condition 2 below:
Condition 1 at least one of n1 L₁(s) is substituted with at least one R₁₀ₐ
Condition 2 R₂ is substituted with at least one R₁₀ₐ

In one or more embodiments, when the first compound satisfies Condition 1, at least one L₁ may be substituted with a C₁-C₂₀ alkyl group, a C₁-C₂₀ alkoxy group, or a C₁-C₂₀ alkylthio group, each unsubstituted or substituted with at least one of deuterium, a hydroxyl group, a C₁-C₂₀ alkyl group, a C₁-C₂₀ alkoxy group, a C₁-C₂₀ alkylthio group, a C₃-C₃₀ carbocyclic group, a C₁-C₃₀ heterocyclic group, a C₇-C₆₀ alkyl aryl group, a C₇-C₆₀ aryl alkyl group, a C₆-C₃₀ aryloxy group, a C₆-C₃₀ arylthio group, a C₂-C₆₀ alkyl heteroaryl group, a C₂-C₆₀ heteroaryl alkyl group, a C₁-C₆₀ heteroaryloxy group, a C₁-C₆₀ heteroarylthio group, —Si(Q₁₁)(Q₁₂)(Q₁₃), —N(Q₁₁)(Q₁₂), or a combination thereof.

In one or more embodiments, when the first compound satisfies Condition 1, at least one L₁ may be substituted with a methyl group, an ethyl group, an n-propyl group, an isopropyl group, an n-butyl group, an isobutyl group, a sec-butyl group, or a tert-butyl group; a C₁-C₂₀ alkoxy group that is unsubstituted or substituted with at least one of a C₁-C₂₀ alkyl group, or a C₁-C₂₀ alkoxy group; or a C₁-C₆₀ alkylthio group that is unsubstituted or substituted with at least one R₁₀ₐ.

In one or more embodiments, when the first compound satisfies Condition 2, R₂ may be substituted with a C₁-C₂₀ alkyl group that is unsubstituted or substituted with deuterium, a hydroxyl group, a C₁-C₂₀ alkyl group, a C₁-C₂₀ alkoxy group, a C₁-C₂₀ alkylthio group, a C₃-C₃₀ carbocyclic group, a C₁-C₃₀ heterocyclic group, a C₇-C₆₀ alkyl aryl group, a C₇-C₆₀ aryl alkyl group, a C₆-C₃₀ aryloxy group, a C₆-C₃₀ arylthio group, a C₂-C₆₀ alkyl heteroaryl group, a C₂-C₆₀ heteroaryl alkyl group, a C₁-C₆₀ heteroaryloxy group, a C₁-C₆₀ heteroarylthio group, —Si(Q₁₁)(Q₁₂)(Q₁₃), —N(Q₁₁)(Q₁₂), or a combination thereof.

In one or more embodiments, when the first compound satisfies Condition 2, R₂ may be:
a C₃-C₁₀ alkyl group that is unsubstituted or substituted with at least one of a C₁-C₁₀ alkyl group, an adamantanyl group, a norbornanyl group, a norbornenyl group, a cyclopentenyl group, a cyclohexenyl group, a cycloheptenyl group, a tetrahydrofuranyl group, a pyrrolidinyl group, a piperidinyl group, a phenyl group, a biphenyl group, a naphthyl group, an indolinyl group, an isoindolinyl group, an isoindolyl group, an indolyl group, or a combination thereof;
‘an adamantanyl group, a norbornanyl group, a norbornenyl group, a tetrahydrofuranyl group, a tetrahydrothiophene group, a pyrrolidinyl group, a piperidinyl group, a phenyl group, a biphenyl group, a naphthyl group, a pyrrolyl group, a thiophenyl group, a furanyl group, an indolinyl group, an isoindolinyl group, an isoindolyl group, an indolyl group, a quinolinyl group, an isoquinolinyl group, a carbazolyl group, a benzofuranyl group, a benzothiophenyl group, a dibenzofuranyl group, or a dibenzothiophenyl group, each unsubstituted or substituted with at least one of a C₁-C₂₀ alkyl group, —Si(Q₃₁)(Q₃₂)(Q₃₃), or a combination thereof; or
—Si(Q₁)(Q₂)(Q₃).

In one or more embodiments, the first compound may be represented by Formula 1-1 or 1-2:

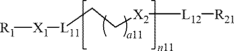

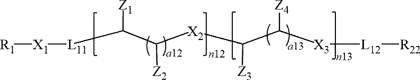

wherein, in Formulae 1-1 and 1-2,
L₁₁ and L₁₂ may each independently be a single bond, a C₁-C₆₀ alkylene group that is unsubstituted or substituted with at least one R₁₀ₐ, a C₂-C₆₀ alkenylene group that is unsubstituted or substituted with at least one R₁₀ₐ, a C₂-C₆₀ alkynylene group that is unsubstituted or substituted with at least one R₁₀ₐ, a C₃-C₁₀ cycloalkylene group that is unsubstituted or substituted with at least one R₁₀ₐ, a C₃-C₁₀ heterocycloalkenylene group that is unsubstituted or substituted with at least one R₁₀ₐ, a C₃-C₁₀ cycloalkenylene group that is unsubstituted or substituted with at least one R₁₀ₐ, or a C₁-C₁₀ heterocycloalkenylene group that is unsubstituted or substituted with at least one R₁₀ₐ,
X₁ to X₃ may each independently be *—B(R₁ₐ)—*’, *—N(R₁ₐ)—*’, *—O—*’, *—P(R₁ₐ)—*’, *—P(═O)(R₁ₐ)—*’, *—S—*’, *—S(═O)—*’, *—S(═O)₂—*’, or *—Si(R₁ₐ)(R_{1b})—*’, and * and *’ each indicate a binding site to a neighboring atom,
R₁ may be hydrogen or deuterium,
R₂₁ may be a C₃-C₂₀ alkyl group that is unsubstituted or substituted with at least one R₁₀ₐ, a C₃-C₂₀ alkenyl group that is unsubstituted or substituted with at least one R₁₀ₐ, a C₃-C₂₀ alkynyl group that is unsubstituted or substituted with at least one R₁₀ₐ, a C₁-C₂₀ alkoxy group that is unsubstituted or substituted with at least one R₁₀ₐ, a C₁-C₂₀ alkylthio group that is unsubstituted or substituted with at least one R₁₀ₐ, a C₃-C₃₀ carbocyclic group that is unsubstituted or substituted with at least one R₁₀ₐ, a C₁-C₃₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₂₂ may be a C₁-C₂₀ alkyl group that is unsubstituted or substituted with at least one R₁₀ₐ, a C₂-C₂₀ alkenyl group that is unsubstituted or substituted with at least one R₁₀ₐ, a C₂-C₂₀ alkynyl group that is unsubstituted or substituted with at least one R₁₀ₐ, a C₁-C₂₀ alkoxy group that is unsubstituted or substituted with at least one R₁₀ₐ, a C₁-C₂₀ alkylthio group that is unsubstituted or substituted with at least one R₁₀ₐ, a C₃-C₃₀ carbocyclic group that is unsubstituted or substituted with at least one R₁₀ₐ, a C₁-C₃₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, or a C₁-C₆₀ heteroarylthio group that is unsubstituted or substituted with at least one R₁₀ₐ,
Z₁ to Z₄ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
at least one of Z₁ to Z₄ may include at least one carbon,
n11 may be an integer from 1 to 5,
n12 and n13 may each be an integer from 0 to 5,
a sum of n12 and n13 may be 1 or greater,
a11 to a13 may each be an integer from 0 to 5, and
R₁₀ₐ,R₁ₐ, R_{1b}, and Q₁ to Q₃ may respectively be as described herein.

In one or more embodiments, L₁₁ and L₁₂ may each independently be a single bond or a C₁-C₁₀ alkylene group that is unsubstituted or substituted with at least one R₁₀ₐ.

In one or more embodiments, L₁₁ and L₁₂ may each independently be a single bond, a methylene group, or an ethylene group.

In one or more embodiments, X₁ to X₃ in Formulae 1-1 and 1-2 may each be *—N(R₁ₐ)—*’, *—O—*’, *—S—*’, or *—Si(R₁ₐ)(R_{1b})—*’, wherein * and *’ each indicate a binding site to a neighboring atom.

In one or more embodiments, R₂₁ may be a C₃-C₂₀ alkyl group that is unsubstituted or substituted with at least one R₁₀ₐ, a C₃-C₃₀ carbocyclic group that is unsubstituted or substituted with at least one R₁₀ₐ, a C₁-C₃₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₁-C₆₀ alkyl heteroaryl group that is unsubstituted or substituted with at least one R₁₀ₐ, or a C₂-C₆₀ heteroaryl alkyl group that is unsubstituted or substituted with at least one R₁₀ₐ.

In one or more embodiments, R₂₁ may be:
a C₃-C₂₀ alkyl group that is unsubstituted or substituted with at least one of deuterium, —CD₃, —CD₂H, —CDH₂, —CF₃, —CF₂H, —CFH₂, a hydroxyl group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a tetrahydrofuranyl group, a pyrrolidinyl group, a piperidinyl group, a phenyl group, a biphenyl group, a naphthyl group, a pyridinyl group, a pyrimidinyl group, an indolinyl group, an isoindolinyl group, an isoindolyl group, an indolyl group, or a combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a tetrahydrofuranyl group, a tetrahydrothiophene group, a pyrrolidinyl group, a piperidinyl group, a phenyl group, a biphenyl group, a naphthyl group, a fluorenyl group, a phenanthrenyl group, an anthracenyl group, a fluoranthenyl group, a triphenylenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolinyl group, an isoindolinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, or a dibenzothiophenyl group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₁-C₂₀ alkylthio group, —Si(Q₃₁)(Q₃₂)(Q₃₃), —N(Q₃₁)(Q₃₂), or a combination thereof; or
— Si(Q₁)(Q₂)(Q₃) or —N(Q₁)(Q₂), and
Q₁ to Q₃ and Q₃₁ to Q₃₃ may each independently be:
   —CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
   an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, or a naphthyl group, each unsubstituted or substituted with at least one of deuterium, a C₁-C₁₀ alkyl group, a phenyl group, or a combination thereof.

In one or more embodiments, R₂₁ may be:
a C₃-C₁₀ alkyl group that is unsubstituted or substituted with at least one of a C₁-C₁₀ alkyl group, an adamantanyl group, a norbornanyl group, a norbornenyl group, a cyclopentenyl group, a cyclohexenyl group, a cycloheptenyl group, a tetrahydrofuranyl group, a pyrrolidinyl group, a piperidinyl group, a phenyl group, a biphenyl group, a naphthyl group, an indolinyl group, an isoindolinyl group, an isoindolyl group, an indolyl group, or a combination thereof;
an adamantanyl group, a norbornanyl group, a norbornenyl group, a tetrahydrofuranyl group, a tetrahydrothiophene group, a pyrrolidinyl group, a piperidinyl group, a phenyl group, a biphenyl group, a naphthyl group, a pyrrolyl group, a thiophenyl group, a furanyl group, an indolinyl group, an isoindolinyl group, an isoindolyl group, an indolyl group, a quinolinyl group, an isoquinolinyl group, a carbazolyl group, a benzofuranyl group, a benzothiophenyl group, a dibenzofuranyl group, or a dibenzothiophenyl group, each unsubstituted or substituted with at least one of a C₁-C₂₀ alkyl group, —Si(Q₃₁)(Q₃₂)(Q₃₃), or a combination thereof; or
—Si(Q₁)(Q₂)(Q₃), and
Q₁ to Q₃ and Q₃₁ to Q₃₃ may each independently be:
   —CH₃ or —CH₂CH₃;
   an n-propyl group, an isopropyl group, a phenyl group, or a naphthyl group, each unsubstituted or substituted with at least one of a C₁-C₁₀ alkyl group, a phenyl group, or a combination thereof.

In one or more embodiments, R₂₂ may be a C₁-C₂₀ alkyl group that is unsubstituted or substituted with at least one R₁₀ₐ.

In one or more embodiments, R₂₂ may be a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, or a tert-pentyl group.

In one or more embodiments, Z₁ to Z₄ may each independently be
hydrogen, deuterium, —F, —Cl, —Br, —I, —SF₅, a hydroxyl group, or a C₁-C₂₀ alkyl group that is unsubstituted or substituted with at least one R₁₀ₐ, or
may include *-(L₁₄-X₄)ₙ₁₄-*’.
L₁₄ may be a C₁-C₆₀ alkylene group that is unsubstituted or substituted with at least one R₁₀ₐ, a C₃-C₁₀ cycloalkylene group that is unsubstituted or substituted with at least one R₁₀ₐ, a C₃-C₁₀ heterocycloalkenylene group that is unsubstituted or substituted with at least one R₁₀ₐ, a C₃-C₁₀ cycloalkenylene group that is unsubstituted or substituted with at least one R₁₀ₐ, or a C₁-C₁₀ heterocycloalkenylene group that is unsubstituted or substituted with at least one R₁₀ₐ,
X₁₄ may be *—B(R₁ₐ)—*’, *—N(R₁ₐ)—*’, *—O—*’, *—P(R₁ₐ)—*’, *—P(═O)(R₁ₐ)—*’, *—S—*’, *—S(═O)—*’, *—S(═O)₂—*’, or *—Si(R₁ₐ)(R_{1b})—*’,
n14 may be an integer from 1 to 5,
* and *’ each indicate a binding site to a neighboring atom, and
R₁ₐ, R_{1b}, and R₁₀ₐ may respectively be as described herein.

In one or more embodiments, at least one of Z₁ to Z₄ may be
a C₁-C₂₀ alkyl group that is unsubstituted or substituted with at least one R₁₀ₐ, or may include *—(L₁₄—X₄)ₙ₁₄—*’,
L₁₄ may be a C₁-C₆₀ alkylene group that is unsubstituted or substituted with at least one R₁₀ₐ, a C₃-C₁₀ cycloalkylene group that is unsubstituted or substituted with at least one R₁₀ₐ, a C₃-C₁₀ heterocycloalkenylene group that is unsubstituted or substituted with at least one R₁₀ₐ, a C₃-C₁₀ cycloalkenylene group that is unsubstituted or substituted with at least one R₁₀ₐ, or a C₁-C₁₀ heterocycloalkenylene group that is unsubstituted or substituted with at least one R₁₀ₐ,
X₁₄ may be *—N(R₁ₐ)—*’, *—O—*’, *—S—*’, or *—Si(R₁ₐ)(R_{1b})—*’,
n14 may be an integer from 1 to 5, and
* and *’ each indicate a binding site to a neighboring atom.

In one or more embodiments, the first compound may be represented by Formula 1-1A, 1-1B, or 1-2A:

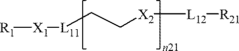

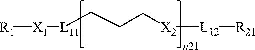

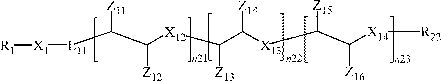

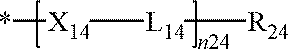

wherein, in Formulae 1-1 A, 1-1B, 1-2A, and 1-Z,
L₁₁, L₁₂, and L₁₄ may each independently be a single bond, a C₁-C₆₀ alkylene group that is unsubstituted or substituted with at least one R₁₀ₐ, a C₂-C₆₀ alkenylene group that is unsubstituted or substituted with at least one R₁₀ₐ, a C₂-C₆₀alkynylene group that is unsubstituted or substituted with at least one R₁₀ₐ, a C₃-C₁₀ cycloalkylene group that is unsubstituted or substituted with at least one R₁₀ₐ, a C₃-C₁₀ heterocycloalkenylene group that is unsubstituted or substituted with at least one R₁₀ₐ, a C₃-C₁₀ cycloalkenylene group that is unsubstituted or substituted with at least one R₁₀ₐ, or a C₁-C₁₀ heterocycloalkenylene group that is unsubstituted or substituted with at least one R₁₀ₐ,
X₁, X₂, and X₁₁ to X₁₄ may each independently be *—B(R₁ₐ)—*’, *—N(R₁ₐ)—*’, *—O—*’, *-P(R₁ₐ)-*’, *—P(═O)(R₁ₐ)—*’, *—S—*’, *—S(═O)—*’, *—S(═O)₂—*’, or *—Si(R₁ₐ)(R_{1b})—*’, and * and *’ each indicate a binding site to a neighboring atom,
R₁ may be hydrogen or deuterium,
R₂₁ may be a C₃-C₂₀ alkyl group that is unsubstituted or substituted with at least one R₁₀ₐ, a C₃-C₂₀ alkenyl group that is unsubstituted or substituted with at least one R₁₀ₐ, a C₃-C₂₀ alkynyl group that is unsubstituted or substituted with at least one R₁₀ₐ, a C₁-C₂₀ alkoxy group that is unsubstituted or substituted with at least one R₁₀ₐ, a C₁-C₆₀ alkylthio group that is unsubstituted or substituted with at least one R₁₀ₐ, a C₃-C₃₀ carbocyclic group that is unsubstituted or substituted with at least one R₁₀ₐ, a C₁-C₃₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ, —Si(Q₁)(Q₂)(Q₃), or —N(Q₁)(Q₂),
R₂₂ and R₂₄ may each independently be a C₁-C₂₀ alkyl group that is unsubstituted or substituted with at least one R₁₀ₐ, a C₂-C₂₀ alkenyl group that is unsubstituted or substituted with at least one R₁₀ₐ, a C₂-C₂₀ alkynyl group that is unsubstituted or substituted with at least one R₁₀ₐ, a C₁-C₂₀ alkoxy group that is unsubstituted or substituted with at least one R₁₀ₐ, a C₁-C₆₀ alkylthio group that is unsubstituted or substituted with at least one R₁₀ₐ, a C₃-C₃₀ carbocyclic group that is unsubstituted or substituted with at least one R₁₀ₐ, or a C₁-C₃₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, or a C₁-C₆₀ heteroarylthio group that is unsubstituted or substituted with at least one R₁₀ₐ,
Z₁₁ to Z₁₆ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
at least one of Z₁₁ to Z₁₆ may be a C₁-C₆₀ alkyl group that is unsubstituted or substituted with at least one R₁₀ₐ, or may include a group represented by Formula 1-Z,
n21 and n24 may each independently be an integer from 1 to 5,
n22 and n23 may each independently be an integer from 0 to 5, and
R₁ₐ, R_{1b}, R₁₀ₐ, and Q₁ to Q₃ may respectively be as described herein.

In one or more embodiments, the first compound may be one of Compounds 1 to 26 below:

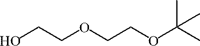

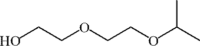

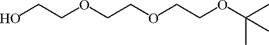

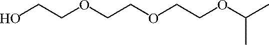

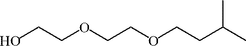

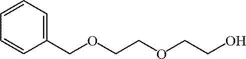 [SMILES: OCCOCCOCc1ccccc1]

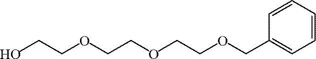 [SMILES: OCCOCCOCCOCc1ccccc1]

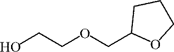

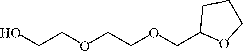 [SMILES: OCCOCCOCC1CCCO1]

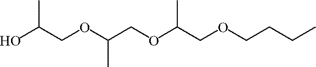 [SMILES: CCCCOCC(C)OCC(C)OCC(C)O]

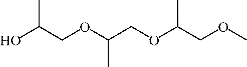

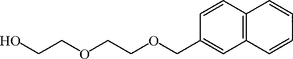 [SMILES: OCCOCCOCc1ccc2ccccc2c1]

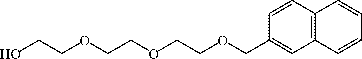 [SMILES: OCCOCCOCCOCc1ccc2ccccc2c1]

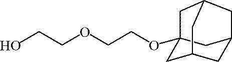 [SMILES: OCCOCCOC12CC3CC(CC(C3)C1)C2]

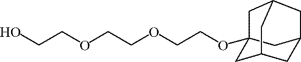 [SMILES: OCCOCCOCCOC12CC3CC(CC(C3)C1)C2]

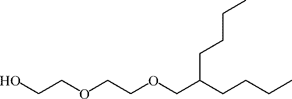 [SMILES: CCCCC(CCCC)COCCOCCO]

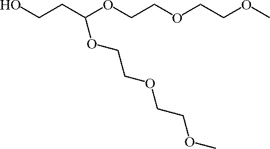 [SMILES: COCCOCCOC(CCO)OCCOCCOC]

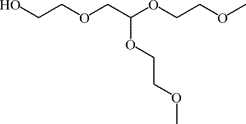 [SMILES: COCCOC(COCCO)OCCOC]

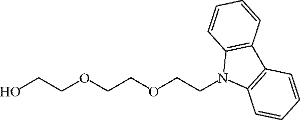 [SMILES: OCCOCCOCCn1c2ccccc2c2ccccc21]

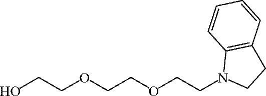 [SMILES: OCCOCCOCCN1CCc2ccccc21]

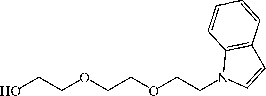 [SMILES: OCCOCCOCCn1ccc2ccccc21]

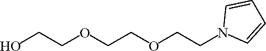 [SMILES: OCCOCCOCCn1cccc1]

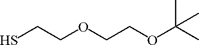

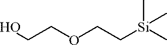

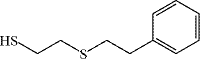 [SMILES: SCCSCCc1ccccc1]

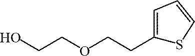 [SMILES: OCCOCCc1cccs1]

The solvent including the first compound may have a boiling point of about 200° C. or greater, about 210° C. or greater, or about 220° C. or greater.

The solvent including the first compound may have a viscosity of about 35 centipoise (cP) or less, about 30 cP or less, or about 25 cP or less.

The solvent including the first compound may have a surface tension of about 45 dynes per centimeter (dyn/cm) or less, about 42 dyn/cm or less, or about 40 dyn/cm or less.

Second compound

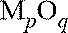

M in Formula 2 is Zn, Ti, Zr, Sn, W, Ta, Ni, Mo, Cu, or V.

p and q in Formula 2 are each independently a number from 1 to 5.

In one or more embodiments, M may be Zn. In one or more embodiments, M may be Zn, and p and q may each be 1.

In one or more embodiments, the second compound may be a zinc-containing oxide.

In one or more embodiments, the second compound may be ZnO, ZnMgO, ZnAlO, ZnSiO, ZnYbO, TiO₂, WO₃, W₂O₃, WO₂, W₂O₃, or a combination thereof.

In one or more embodiments, second compound may be represented by Formula 2-1 below:

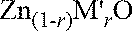

wherein M′ in Formula 2-1 may be Mg, Co, Ni, Zr, Mn, Sn, Y, Al, or a combination thereof.

r in Formula 2-1 may be a number greater than 0 and less than or equal to 0.5.

The metal oxide composition includes the solvent that includes the first compound and the metal oxide that includes the second compound, wherein the first compound has a moiety represented by the formula —X₁—R₁ at one end thereof, and has a bulky substituent at the other end (R₂) thereof or at a main chain (L₁).

Since the solvent includes the first compound, the solvent may have excellent dispersibility with respect to the metal oxide and may have properties suitable for use in an inkjet process.

Also, when an electron transport layer adjacent to quantum dot-containing emission layer is formed by using the metal oxide composition including the solvent, since the solvent include a bulky substituent, the solvent does not in direct contact with the quantum dot of the emission layer, thereby reducing the surface damage of the quantum dot. Therefore, a light-emitting device (for example, a quantum dot light-emitting device) with improved luminescence characteristics may be manufactured by using the metal oxide composition.

The metal oxide composition may include the metal oxide of about 0.5 weight percent (wt%) to about 10 wt%, about 1 wt% to about 7 wt%, or about 2 wt% to about 5 wt%, based on 100 wt% of the solvent.

The metal oxide composition may have a viscosity of about 21 centipoise (cP) or less, about 20 cP or less, or about 19 cP or less. When the viscosity of the metal oxide composition is within this range, the metal oxide composition may be suitable for use in formation of a metal oxide layer of a light-emitting device by using a solution process.

The metal oxide composition may have a surface tension of about 35 dynes per centimeter (dyn/cm) or less, about 34 dyn/cm or less, or about 33 dyn/cm or less. When the surface tension of the metal oxide composition is within this range, the metal oxide composition may be suitable for use in formation of a metal oxide layer of a light-emitting device by using a solution process.

The metal oxide composition may include a solvent, in addition to the first compound. In addition to the first compound, the solvent may be any suitable solvent that may appropriately disperse a metal oxide and a hydrogen cation source, but embodiments are not limited thereto.

In one or more embodiments, in addition to the first compound, the solvent may be an organic solvent.

In one or more embodiments, in addition to the first compound, the solvent may be an alcohol-containing solvent, a chlorine-containing solvent, an ether-containing solvent, an ester-containing solvent, a ketone-containing solvent, an aliphatic hydrocarbon-containing solvent, and an aromatic hydrocarbon-containing solvent, or a combination thereof, but embodiments are not limited thereto.

In one or more embodiments, in addition to the first compound, the solvent may include:

an alcohol-containing solvent such as methanol, ethanol, n-propanol, iso-propanol, n-butanol, iso-butanol, sec-butanol, or t-butanol; a chlorine-containing solvent such as dichloromethane, 1,2-dichloroethane, 1,1,2-trichloroethane, chlorobenzene, or o-dichlorobenzene; an ether-containing solvent such as tetrahydrofuran, dioxane, anisole, 4-methylanisol, or butylphenyl ether; an ester-containing solvent such as ethyl acetate, butyl acetate, methyl benzoate, ethyl benzoate, butyl benzoate, or phenyl benzoate; a ketone-containing solvent such as acetone, methylethylketone, cyclohexanone, or acetophenone; an aliphatic hydrocarbon-containing solvent such as cyclohexane, methylcyclohexane, n-pentane, n-hexane, hexanes, n-heptane, n-octane, n-nonane, n-decane, dodecane, hexadecane, or oxadecane; an aromatic hydrocarbon-containing solvent such as toluene, xylene, mesitylene, ethylbenzene, n-hexylbenzene, cyclohexylbenzene, trimethylbenzene, or tetrahydronaphthalene; or a combination thereof, but embodiments are not limited thereto.

### Light-Emitting Device

Also provided is a light-emitting device including a first electrode; a second electrode facing the first electrode; an interlayer arranged between the first electrode and the second electrode; and a metal oxide layer formed by using the metal oxide composition.

In one or more embodiments, the emission layer may include a quantum dot. For example, the emission layer may include a plurality of quantum dots.

As used herein, “a quantum dot” refers to a crystal of a semiconductor compound and may include any material capable of emitting light of various emission wavelengths according to the size of the crystal.

The quantum dot in the emission layer may include a Group II-VI semiconductor compound, a Group III-V semiconductor compound, a Group III-VI semiconductor compound, a Group I-III-VI semiconductor compound, a Group IV-VI semiconductor compound, a Group IV element or compound, or a combination thereof.

Examples of the Group II-VI semiconductor compound may include: a binary compound, such as CdS, CdSe, CdTe, ZnS, ZnSe, ZnTe, ZnO, HgS, HgSe, HgTe, MgSe, MgS, or a combination thereof; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or a combination thereof; a quaternary compound, such as CdZnSeS, CdZnSeTe, CdZnSTe, CdHgSeS, CdHgSeTe, CdHgSTe, HgZnSeS, HgZnSeTe, HgZnSTe, or a combination thereof; or a combination thereof.

Examples of the Group III-V semiconductor compound may include: a binary compound, such as GaN, GaP, GaAs, GaSb, AIN, AIP, AlAs, AlSb, InN, InP, InAs, InSb, or a combination thereof; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, or a combination thereof; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a combination thereof; or a combination thereof. In one or more embodiments, the Group III-V semiconductor compound may further include one or more Group II elements. Examples of the Group III-V semiconductor compound further including Group II elements may include InZnP, InGaZnP, InAlZnP, a combination thereof, or the like.

Examples of the Group III-VI semiconductor compound may include: a binary compound, such as GaS, GaSe, Ga₂Se₃, GaTe, InS, InSe, In₂S₃, In₂Se₃, InTe, or a combination thereof; a ternary compound, such as InGaS₃, InGaSe₃, or a combination thereof; or a combination thereof.

Examples of the Group I-III-VI semiconductor compound may include: a ternary compound, such as AgInS, AgInS₂, CuInS, CuInS₂, CuGaO₂, AgGaO₂, AgAlO₂, or a combination thereof.

Examples of the Group IV-VI semiconductor compound may include: a binary compound, such as SnS, SnSe, SnTe, PbS, PbSe, PbTe, or the like, or a combination thereof; a ternary compound, such as SnSeS, SnSeTe, SnSTe, PbSeS, PbSeTe, PbSTe, SnPbS, SnPbSe, SnPbTe, or the like, or a combination thereof; a quaternary compound, such as SnPbSSe, SnPbSeTe, SnPbSTe, or the like; or a combination thereof.

The Group IV element or compound may include: a single element compound, such as Si, Ge, or a combination thereof; a binary compound, such as SiC, SiGe, or a combination thereof; or a combination thereof.

Each element included in a multi-element compound such as the binary compound, ternary compound and quaternary compound, may exist in a particle with a uniform concentration or non-uniform concentration.

In one or more embodiments, the quantum dot may have a single structure or a dual core-shell structure. In the case of the quantum dot having a single structure, the concentration of each element included in the corresponding quantum dot is uniform. In one or more embodiments, the material contained in the core and the material contained in the shell may be different from each other.

In one or more embodiments, the core may include at least one of Zn, Te, Se, Cd, In, P, or a combination thereof. In one or more embodiments, the core may include InP, InZnP, ZnSe, ZnTeS, ZnSeTe, or a combination thereof.

The shell of the quantum dot may act as a protective layer to prevent chemical degeneration of the core to maintain semiconductor characteristics and/or as a charging layer to impart electrophoretic characteristics to the quantum dot. The shell may be a single layer or a multi-layer. The element presented in the interface between the core and the shell of the quantum dot may have a concentration gradient that decreases toward the center of the quantum dot.

Examples of the shell of the quantum dot may be an oxide of metal, metalloid, or non-metal, a semiconductor compound, and a combination thereof. Examples of the oxide of metal, metalloid, or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound, such as MgAl₂O₄, CoFe₂O₄, NiFe₂O₄, CoMn₂O₄, or a combination thereof. Examples of the semiconductor compound may include, as described herein, a Group II-VI semiconductor compound, a Group III-V semiconductor compound, a Group III-VI semiconductor compound, a Group I-III-VI semiconductor compound, a Group IV-VI semiconductor compound, or a combination thereof. In one or more embodiments, the semiconductor compound may include CdS, CdSe, CdTe, ZnS, ZnSe, ZnTe, ZnSeS, ZnTeS, ZnSeTe, GaAs, GaP, GaSb, HgS, HgSe, HgTe, InAs, InP, InGaP, InSb, AlAs, AlP, AlSb, or a combination thereof.

In one or more embodiments, the shell may have a composition different from the composition of the core, and the shell may include ZnS, ZnSe, ZnSeS, ZnTeS, ZnSeTe, or a combination thereof.

The quantum dot may have a full width at half maximum (FWHM) of a spectrum of an emission wavelength of about 45 nm or less, about 40 nm or less, or about 30 nm or less. When the FWHM of the quantum dot is within this range, color purity and/or color reproducibility may be improved. In addition, since the light emitted through the quantum dot is emitted in all directions, the wide viewing angle can be improved.

In one or more embodiments, a diameter or particle size (D50) of the quantum dot may be in a range of about 1 nm to about 20 nm. When the average diameter of quantum dots is within any of these ranges, specific behavior as quantum dots may be achieved, and excellent dispersibility of the composition may be obtained. In addition, the quantum dot may be spherical, pyramidal, multi-arm, or cubic nanoparticles, nanotubes, nanowires, nanofibers, nano-plate particles, combinations thereof, or the like.

Since the energy band gap can be adjusted by controlling the size of the quantum dot, light having various wavelength bands can be obtained from the quantum dot emission layer. Therefore, by using quantum dots of different sizes, a light-emitting device that emits light of various wavelengths may be implemented. In one or more embodiments, the size of the quantum dot may be selected to emit red, green and/or blue light. In addition, the size of the quantum dot may be configured to emit white light by combining light of various colors.

The quantum dot may be synthesized by a wet chemical process, a metal organic chemical vapor deposition process, a molecular beam epitaxy process, or any process similar thereto.

According to the wet chemical process, a precursor material is mixed with an organic solvent to grow a quantum dot particle crystal. When the crystal grows, the organic solvent naturally acts as a dispersant coordinated on the surface of the quantum dot crystal and controls the growth of the crystal so that the growth of quantum dot particles may be controlled through a process which is more easily performed than vapor deposition methods, such as metal organic chemical vapor deposition (MOCVD) or molecular beam epitaxy (MBE), and which requires lower costs.

The emission layer may include a monolayer of quantum dots. In one or more embodiments, the emission layer may include a monolayer of quantum dots from about 2 layers to about 20 layers.

A thickness of the emission layer may be in a range of about 5 nm to about 200 nm, about 10 nm to about 150 nm, or for example, about 10 nm to about 100 nm.

In one or more embodiments, the metal oxide layer may be a layer formed by using the metal oxide composition according to one or more embodiments. In one or more embodiments, the metal oxide layer may be formed by an inkjet process.

In one or more embodiments, the first electrode may be an anode, the second electrode may be a cathode, the light-emitting device may further include a hole transport region arranged between the first electrode and the emission layer and an electron transport region arranged between the emission layer and the second electrode, and the hole transport region or the electron transport region may include the metal oxide layer.

The hole transport region may include a hole injection layer, a hole transport layer, an emission auxiliary layer, an electron blocking layer, or a combination thereof. The metal oxide layer may be at least one of the hole injection layer, the hole transport layer, the emission auxiliary layer, and the electron blocking layer.

The electron transport region may include at least one of a buffer layer, a hole blocking layer, an electron control layer, an electron transport layer, an electron injection layer, or a combination thereof. The metal oxide layer may be at least one of the buffer layer, the hole blocking layer, the electron transport layer, the electron injection layer, or a combination thereof.

In one or more embodiments, the metal oxide layer may be in direct contact with the emission layer. In one or more embodiments, after the emission layer is formed, the metal oxide layer may be formed on the emission layer. For example, the metal oxide layer may be formed directly on a surface of the emission layer (e.g., directly on the emission layer). In one or more embodiments, after the metal oxide layer is formed, the emission layer may be formed on the metal oxide layer. For example, the emission layer may be formed directly on a surface of the metal oxide layer (e.g., directly on the metal oxide layer).

In one or more embodiments, the emission layer may include quantum dots, and when a metal oxide layer is formed on the quantum dot emission layer by using the metal oxide composition, the surface damage of the quantum dots is reduced, and thus, a quantum dot light-emitting device with improved luminescence characteristics may be manufactured.

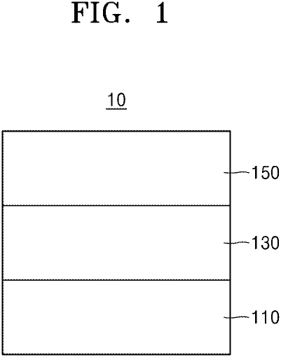

### Description of FIG. 1

FIG. 1 is a schematic cross-sectional view of a light-emitting device 10 according to one or more embodiments. The light-emitting device 10 includes a first electrode 110, an interlayer 130, and a second electrode 150.

Hereinafter, a structure of the light-emitting device 10 according to one or more embodiments and a method of manufacturing the light-emitting device 10 will be described in connection with FIG. 1.

### First Electrode 110

In FIG. 1, a substrate may be additionally located under the first electrode 110 or above the second electrode 150. As the substrate, a glass substrate or a plastic substrate may be used. In one or more embodiments, the substrate may be a flexible substrate, and may include plastics with excellent heat resistance and durability, such as polyimide, polyethylene terephthalate (PET), polycarbonate, polyethylene naphthalate, polyarylate (PAR), polyetherimide, or a combination thereof.

The first electrode 110 may be formed by, for example, depositing or sputtering a material for forming the first electrode 110 on the substrate. When the first electrode 110 is an anode, a material for forming the first electrode 110 may be a high work function material that facilitates injection of holes.

The first electrode 110 may be a reflective electrode, a semi-transmissive electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or a combinations thereof. In one or more embodiments, when the first electrode 110 is a semi-transmissive electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or a combination thereof may be used as a material for forming a first electrode.

The first electrode 110 may have a single-layered structure consisting of a single layer or a multilayer structure including a plurality of layers. In one or more embodiments, the first electrode 110 may have a three-layered structure of ITO/Ag/ITO.

### Interlayer 130

The interlayer 130 may be located on the first electrode 110. The interlayer 130 may include an emission layer.

The interlayer 130 may further include a hole transport region between the first electrode 110 and the emission layer and an electron transport region between the emission layer and the second electrode 150.

The interlayer 130 may further include metal-containing compounds such as organometallic compounds, inorganic materials such as quantum dots, and the like, in addition to various organic materials.

In one or more embodiments, the interlayer 130 may include, i) two or more emitting units sequentially stacked between the first electrode 110 and the second electrode 150, and ii) a charge generation layer located between the two emitting units. When the interlayer 130 includes emitting units and a charge generation layer as described above, the light-emitting device 10 may be a tandem light-emitting device.

### Hole Transport Region in Interlayer 130

The hole transport region may have: i) a single-layered structure consisting of a single layer consisting of a single material, ii) a single-layered structure consisting of a single layer consisting of a plurality of different materials, or iii) a multi-layered structure including a plurality of layers including different materials.

In one or more embodiments, the electron transport region may further include the metal oxide layer as described above.

The hole transport region may include a hole injection layer, a hole transport layer, an emission auxiliary layer, an electron blocking layer, or a combination thereof.

For example, the hole transport region may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, the layers of each structure being stacked sequentially from the first electrode 110.

The hole transport region may include a compound represented by Formula 201, a compound represented by Formula 202, or a combination thereof:

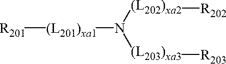

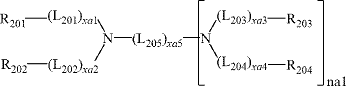

wherein, in Formulae 201 and 202,
L₂₀₁ to L₂₀₄ may each independently be a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
L₂₀₅ may be *—O—*’, *—S—*’, *—N(Q₂₀₁)—*’, a C₁-C₂₀ alkylene group that is unsubstituted or substituted with at least one R₁₀ₐ, a C₂-C₂₀ alkenylene group that is unsubstituted or substituted with at least one R₁₀ₐ, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
R₂₀₁ and R₂₀₂ may optionally be linked to each other, via a single bond, a C₁-C₅ alkylene group that is unsubstituted or substituted with at least one R₁₀ₐ, or a C₂-C₅ alkenylene group that is unsubstituted or substituted with at least one R₁₀ₐ, to form a C₈-C₆₀ polycyclic group (for example, a carbazole group or the like) unsubstituted or substituted with at least one R₁₀ₐ (for example, Compound HT16),
R₂₀₃ and R₂₀₄ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ, to form a C₈-C₆₀ polycyclic group that is unsubstituted or substituted with at least one R₁₀ₐ, and
na1 may be an integer from 1 to 4.

In one or more embodiments, each of Formulae 201 and 202 may include at least one of groups represented by Formulae CY201 to CY217:

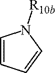

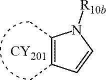

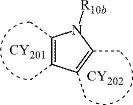

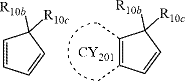

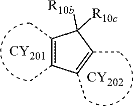

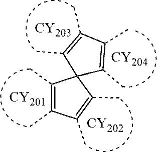

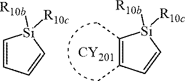

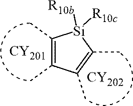

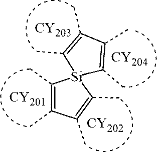

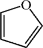

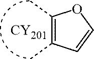

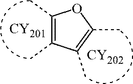

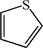

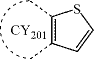

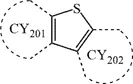

wherein in Formulae CY201 to CY217, R_{10b} and R_{10c} may each be as described with respect to R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described herein.

In one or more embodiments, ring CY₂₀₁ to ring CY₂₀₄ in Formulae CY201 to CY217 may each independently be a phenyl group, a naphthalene group, a phenanthrene group, or an anthracene group.

In one or more embodiments, each of Formulae 201 and 202 may include at least one of groups represented by Formulae CY201 to CY203.

In one or more embodiments, Formula 201 may include at least one of the groups represented by Formulae CY201 to CY203 or at least one of the groups represented by Formulae CY204 to CY217.

In one or more embodiments, xa1 in Formula 201 may be 1, R₂₀₁ may be a group represented by one of Formulae CY201 to CY203, xa2 may be 0, and R₂₀₂ may be a group represented by one of Formulae CY204 to CY207.

In one or more embodiments, each of Formulae 201 and 202 may not include groups represented by Formulae CY201 to CY203.

In one or more embodiments, each of Formulae 201 and 202 may not include groups represented by Formulae CY201 to CY203, and may include at least one of the groups represented by Formulae CY204 to CY217.

In one or more embodiments, each of Formulae 201 and 202 may not include the groups represented by Formulae CY201 to CY217.

In one or more embodiments, the hole transport region may include one of Compounds HT1 to HT46, 4,4′,4″-tris(3-methylphenylphenylamino)triphenylamine (m-MTDATA), 4,4′,4″-tris(N,N-diphenylamino)triphenylamine (TDATA), 4,4′,4″-tris{N-(2-naphthyl)-N-phenylamino}-triphenylamine (2-TNATA), N,N′-di(1-naphthyl)-N,N′-diphenylbenzidine (NPB), β-NPB, N,N′-bis(3-methylphenyl)-N,N′-diphenyl-[1,1-biphenyl]-4,4′-diamine (TPD), spiro-TPD, spiro-NPB, methylated NPB, 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or a combination thereof:

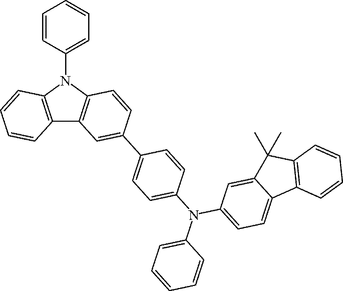 [SMILES: CC1(C)c2ccccc2-c2ccc(N(c3ccccc3)c3ccc(-c4ccc5c(c4)c4ccccc4n5-c4ccccc4)cc3)cc21]

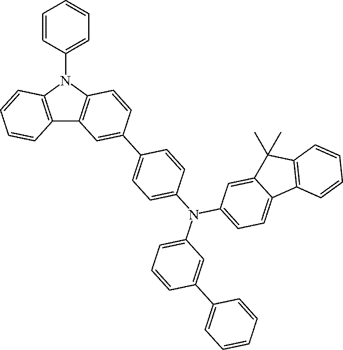 [SMILES: CC1(C)c2ccccc2-c2ccc(N(c3ccc(-c4ccc5c(c4)c4ccccc4n5-c4ccccc4)cc3)c3cccc(-c4ccccc4)c3)cc21]

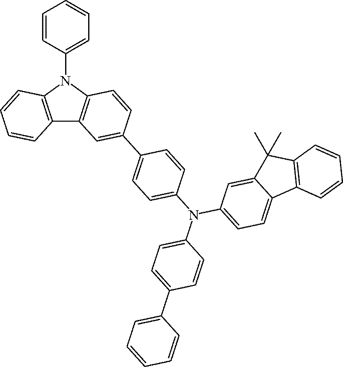 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21]

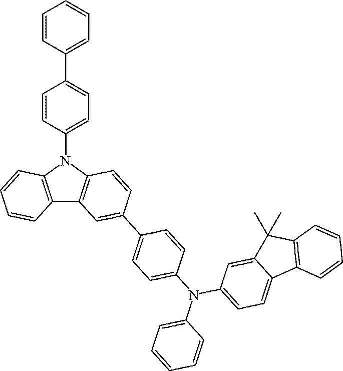 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21]

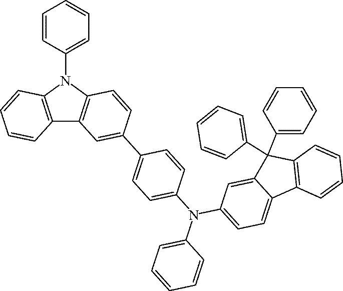 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1]

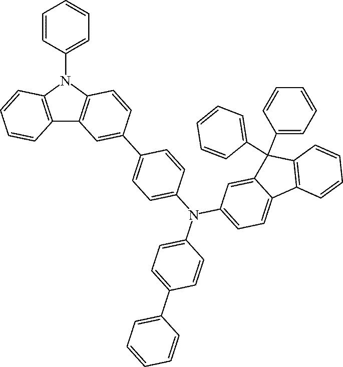 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

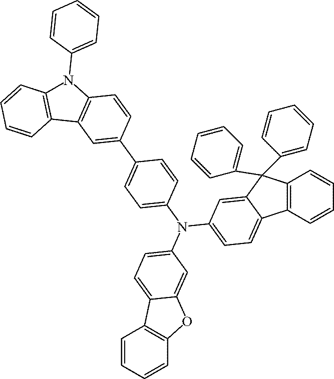 [SMILES: c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1]

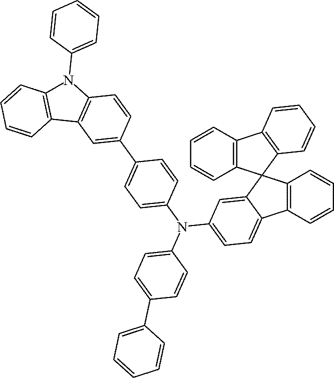 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

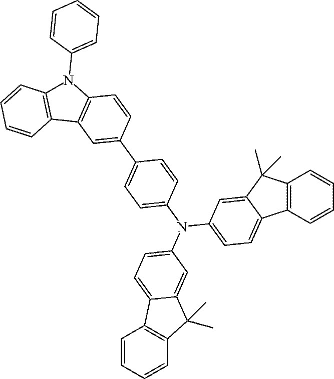 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

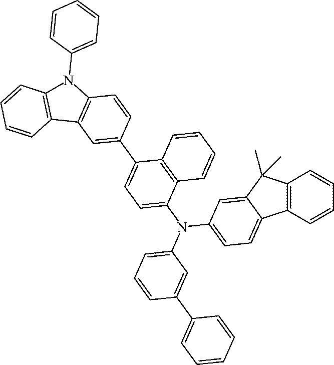 [SMILES: CC1(C)c2ccccc2-c2ccc(N(c3cccc(-c4ccccc4)c3)c3ccc(-c4ccc5c(c4)c4ccccc4n5-c4ccccc4)c4ccccc34)cc21]

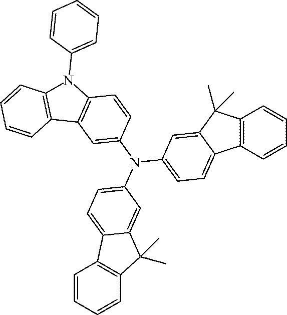 [SMILES: CC1(C)c2ccccc2-c2ccc(N(c3ccc4c(c3)C(C)(C)c3ccccc3-4)c3ccc4c(c3)c3ccccc3n4-c3ccccc3)cc21]

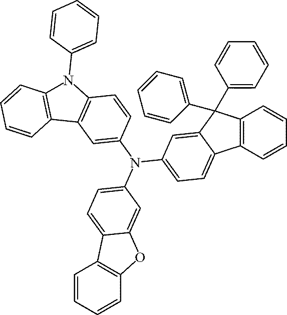 [SMILES: c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

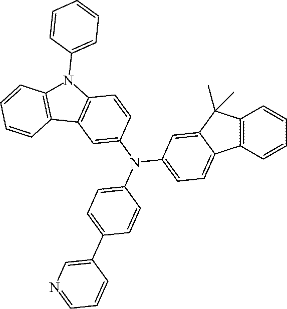 [SMILES: CC1(C)c2ccccc2-c2ccc(N(c3ccc(-c4cccnc4)cc3)c3ccc4c(c3)c3ccccc3n4-c3ccccc3)cc21]

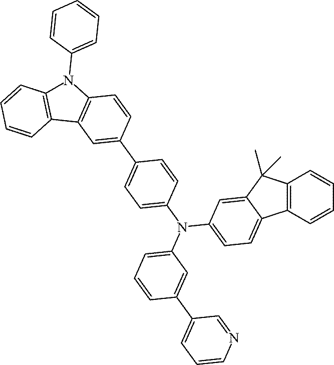 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21]

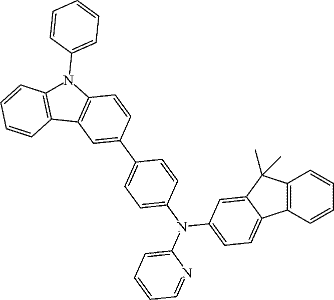 [SMILES: CC1(C)c2ccccc2-c2ccc(N(c3ccc(-c4ccc5c(c4)c4ccccc4n5-c4ccccc4)cc3)c3ccccn3)cc21]

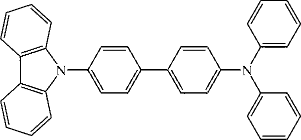 [SMILES: c1ccc(N(c2ccccc2)c2ccc(-c3ccc(-n4c5ccccc5c5ccccc54)cc3)cc2)cc1]

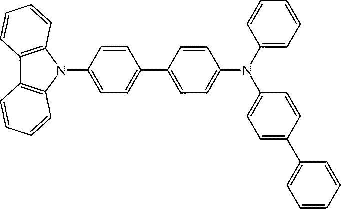 [SMILES: c1ccc(-c2ccc(N(c3ccccc3)c3ccc(-c4ccc(-n5c6ccccc6c6ccccc65)cc4)cc3)cc2)cc1]

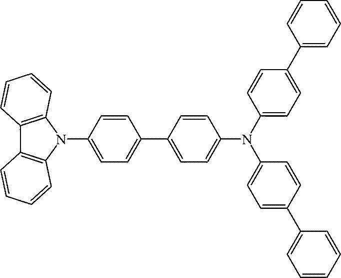 [SMILES: c1ccc(-c2ccc(N(c3ccc(-c4ccccc4)cc3)c3ccc(-c4ccc(-n5c6ccccc6c6ccccc65)cc4)cc3)cc2)cc1]

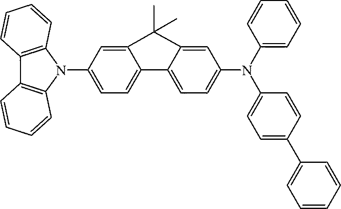 [SMILES: CC1(C)c2cc(N(c3ccccc3)c3ccc(-c4ccccc4)cc3)ccc2-c2ccc(-n3c4ccccc4c4ccccc43)cc21]

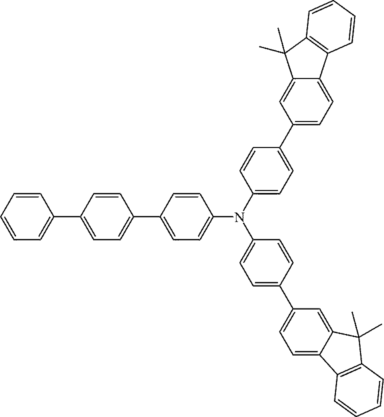 [SMILES: CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

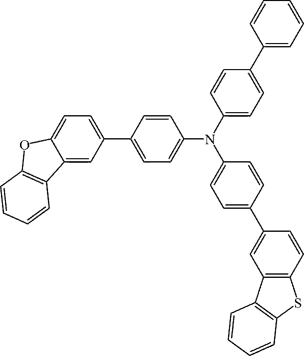 [SMILES: c1ccc(-c2ccc(N(c3ccc(-c4ccc5oc6ccccc6c5c4)cc3)c3ccc(-c4ccc5sc6ccccc6c5c4)cc3)cc2)cc1]

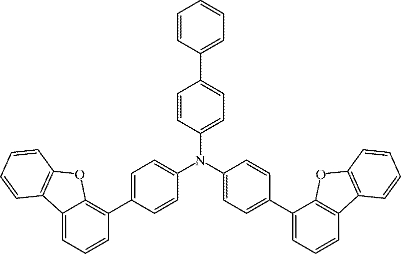 [SMILES: c1ccc(-c2ccc(N(c3ccc(-c4cccc5c4oc4ccccc45)cc3)c3ccc(-c4cccc5c4oc4ccccc45)cc3)cc2)cc1]

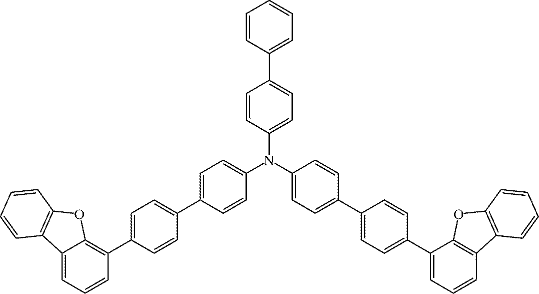 [SMILES: c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

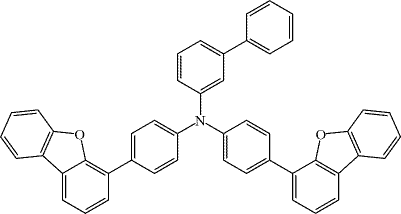 [SMILES: c1ccc(-c2cccc(N(c3ccc(-c4cccc5c4oc4ccccc45)cc3)c3ccc(-c4cccc5c4oc4ccccc45)cc3)c2)cc1]

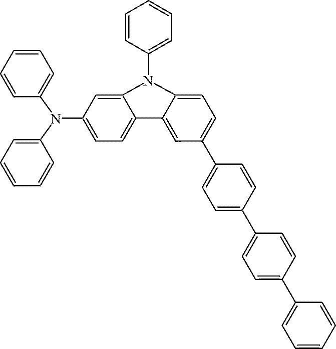 [SMILES: c1ccc(-c2ccc(-c3ccc(-c4ccc5c(c4)c4ccc(N(c6ccccc6)c6ccccc6)cc4n5-c4ccccc4)cc3)cc2)cc1]

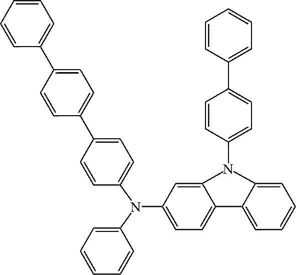 [SMILES: c1ccc(-c2ccc(-c3ccc(N(c4ccccc4)c4ccc5c6ccccc6n(-c6ccc(-c7ccccc7)cc6)c5c4)cc3)cc2)cc1]

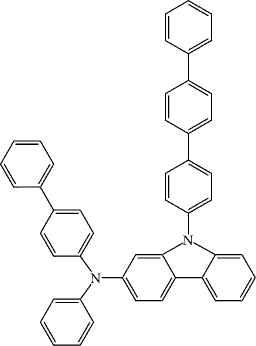 [SMILES: c1ccc(-c2ccc(-c3ccc(-n4c5ccccc5c5ccc(N(c6ccccc6)c6ccc(-c7ccccc7)cc6)cc54)cc3)cc2)cc1]

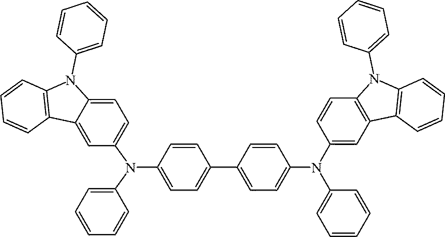 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

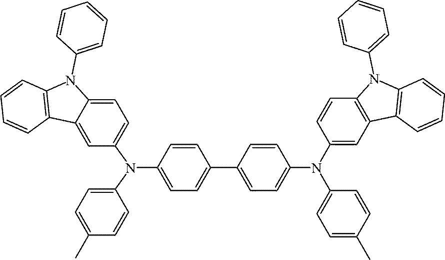 [SMILES: Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1]

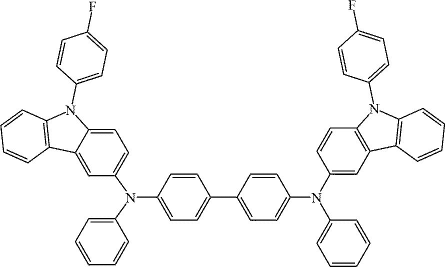 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

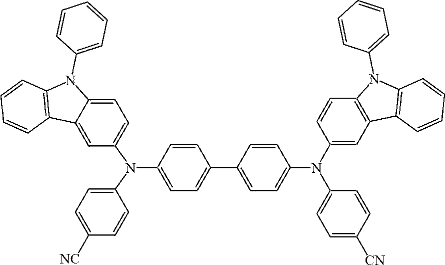

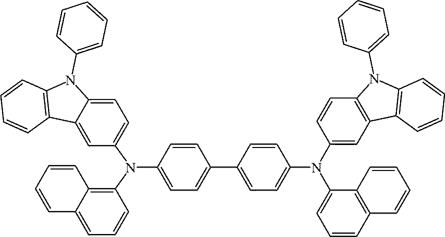 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1]

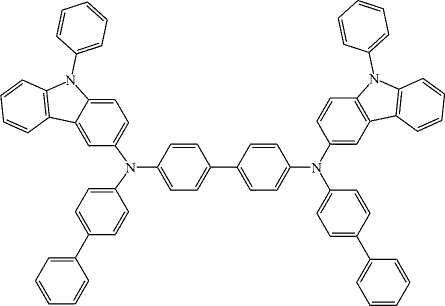 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1]

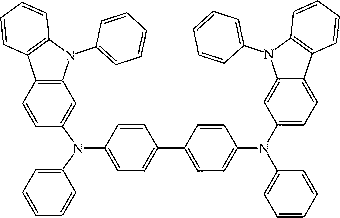 [SMILES: c1ccc(N(c2ccc(-c3ccc(N(c4ccccc4)c4ccc5c6ccccc6n(-c6ccccc6)c5c4)cc3)cc2)c2ccc3c4ccccc4n(-c4ccccc4)c3c2)cc1]

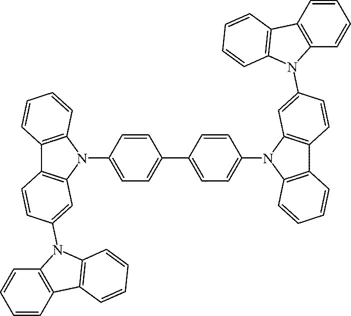 [SMILES: c1ccc2c(c1)c1ccccc1n2-c1ccc2c3ccccc3n(-c3ccc(-c4ccc(-n5c6ccccc6c6ccc(-n7c8ccccc8c8ccccc87)cc65)cc4)cc3)c2c1]

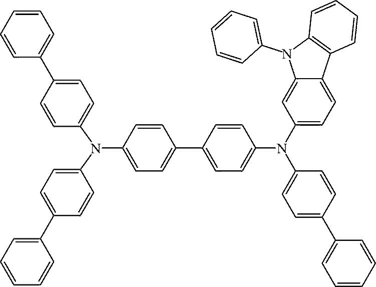 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1]

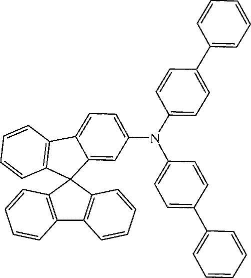 [SMILES: c1ccc(-c2ccc(N(c3ccc(-c4ccccc4)cc3)c3ccc4c(c3)C3(c5ccccc5-c5ccccc53)c3ccccc3-4)cc2)cc1]

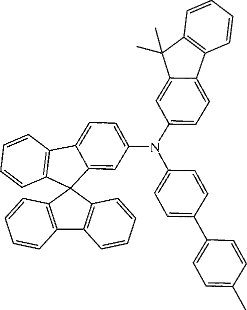 [SMILES: Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1]

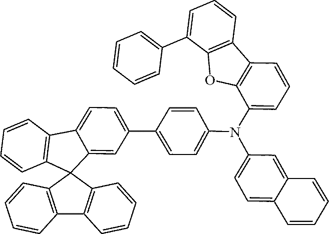 [SMILES: c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

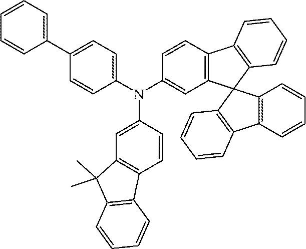 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21]

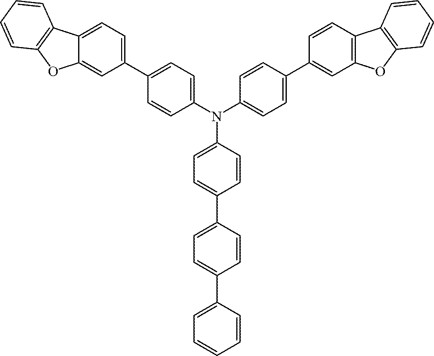 [SMILES: c1ccc(-c2ccc(-c3ccc(N(c4ccc(-c5ccc6c(c5)oc5ccccc56)cc4)c4ccc(-c5ccc6c(c5)oc5ccccc56)cc4)cc3)cc2)cc1]

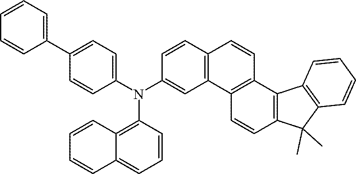 [SMILES: CC1(C)c2ccccc2-c2c1ccc1c2ccc2ccc(N(c3ccc(-c4ccccc4)cc3)c3cccc4ccccc34)cc21]

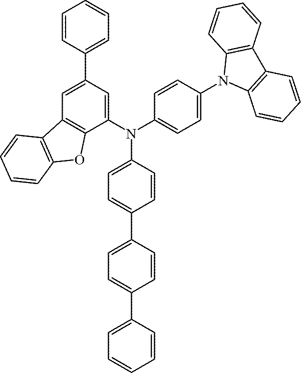 [SMILES: c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

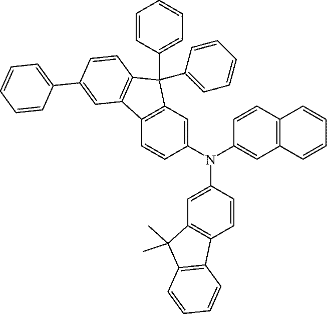 [SMILES: CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21]

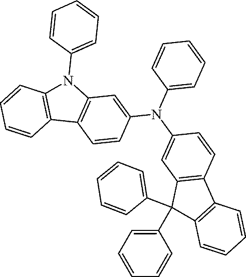 [SMILES: c1ccc(N(c2ccc3c(c2)C(c2ccccc2)(c2ccccc2)c2ccccc2-3)c2ccc3c4ccccc4n(-c4ccccc4)c3c2)cc1]

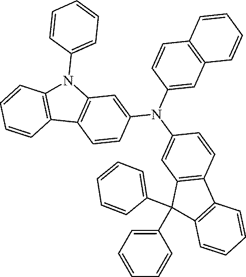 [SMILES: c1ccc(-n2c3ccccc3c3ccc(N(c4ccc5c(c4)C(c4ccccc4)(c4ccccc4)c4ccccc4-5)c4ccc5ccccc5c4)cc32)cc1]

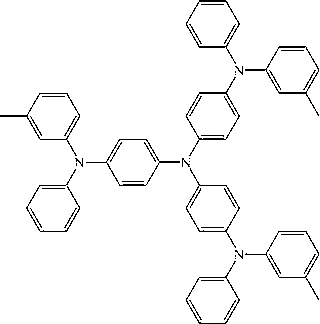

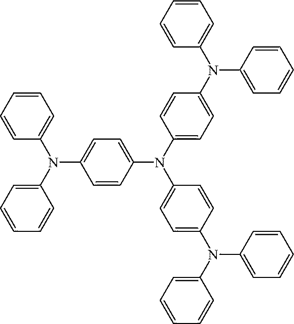 [SMILES: c1ccc(N(c2ccccc2)c2ccc(N(c3ccc(N(c4ccccc4)c4ccccc4)cc3)c3ccc(N(c4ccccc4)c4ccccc4)cc3)cc2)cc1]

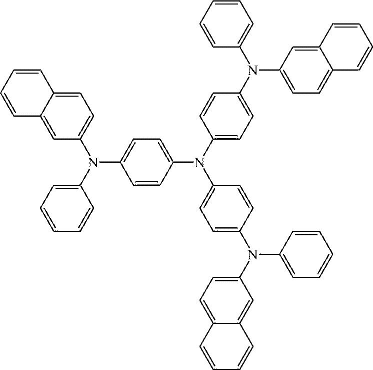 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

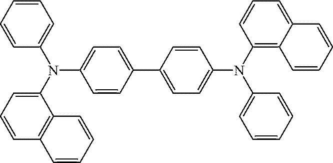 [SMILES: c1ccc(N(c2ccc(-c3ccc(N(c4ccccc4)c4cccc5ccccc45)cc3)cc2)c2cccc3ccccc23)cc1]

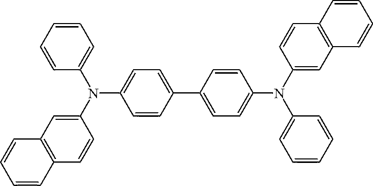 [SMILES: c1ccc(N(c2ccc(-c3ccc(N(c4ccccc4)c4ccc5ccccc5c4)cc3)cc2)c2ccc3ccccc3c2)cc1]

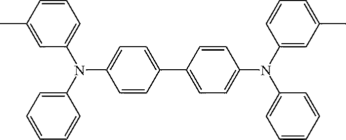

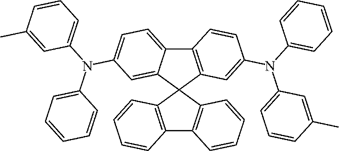

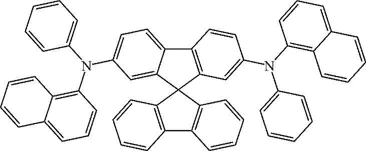 [SMILES: c1ccc(N(c2ccc3c(c2)C2(c4ccccc4-c4ccccc42)c2cc(N(c4ccccc4)c4cccc5ccccc45)ccc2-3)c2cccc3ccccc23)cc1]

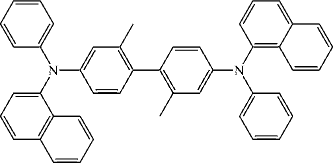 [SMILES: Cc1cc(N(c2ccccc2)c2cccc3ccccc23)ccc1-c1ccc(N(c2ccccc2)c2cccc3ccccc23)cc1C]

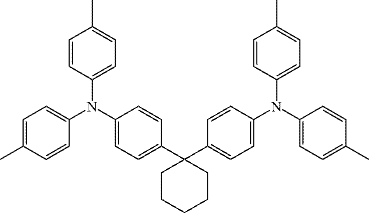

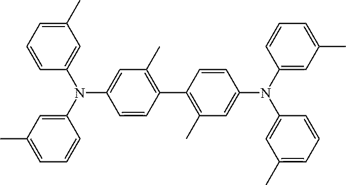

A thickness of the hole transport region may be in a range of about 50 angstroms (Å) to about 10,000 Å, for example, about 100 Å to about 4,000 Å. When the hole transport region includes a hole injection layer, a hole transport layer, or a combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer and the hole transport layer are within these ranges, satisfactory hole-transporting characteristics may be obtained without a substantial increase in driving voltage.

The emission auxiliary layer may increase light-emission efficiency by compensating for an optical resonance distance according to the wavelength of light emitted by an emission layer, and the electron blocking layer may block the leakage of electrons from an emission layer to a hole transport region. Materials that may be included in the hole transport region may be included in the emission auxiliary layer and the electron blocking layer.

### P-Dopant

The hole transport region may further include, in addition to these materials, a charge-generation material for the improvement of conductive properties. The charge-generation material may be uniformly or non-uniformly dispersed in the hole transport region (for example, in the form of a single layer consisting of a charge-generation material).

The charge-generation material may be, for example, a p-dopant.

In one or more embodiments, a LUMO energy level of the p-dopant may be about -3.5 electron Volts (eV) or less.

In one or more embodiments, the p-dopant may include a quinone derivative, a cyano group-containing compound, a compound containing element EL1 and element EL2, or a combination thereof.

Examples of the quinone derivative may include TCNQ, F4-TCNQ, and the like.

Examples of the cyano group-containing compound may include HAT-CN, a compound represented by Formula 221 below, or the like.

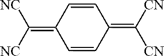

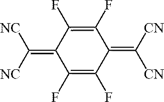

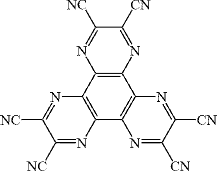

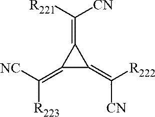

In Formula 221,
R₂₂₁ to R₂₂₃ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, —SF₅, or a combination thereof; or a combination thereof.

In the compound containing element EL1 and element EL2, element EL1 may be metal, metalloid, or a combination thereof, and element EL2 may be non-metal, metalloid, or a combination thereof.

Examples of the metal may include: an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), or the like).

Examples of the metalloid may include silicon (Si), antimony (Sb), and tellurium (Te).

Examples of the non-metal may include oxygen (O) and halogen (for example, F, Cl, Br, I, or the like).

In one or more embodiments, examples of the compound containing element EL1 and element EL2 may include metal oxide, metal halide (for example, metal fluoride, metal chloride, metal bromide, or metal iodide), metalloid halide (for example, metalloid fluoride, metalloid chloride, metalloid bromide, or metalloid iodide), metal telluride, or a combination thereof.

Examples of the metal oxide may include tungsten oxide (for example, WO, W₂O₃, WO₂, WO₃, W₂O₅, or the like), vanadium oxide (for example, VO, V₂O₃, VO₂, V₂O₅, or the like), molybdenum oxide (MoO, Mo₂O₃, MoO₂, MoO₃, Mo₂O₅, or the like), and rhenium oxide (for example, ReO₃, or the like).

Examples of the metal halide may include alkali metal halide, alkaline earth metal halide, transition metal halide, post-transition metal halide, and lanthanide metal halide.

Examples of the alkali metal halide may include at least one of LiF, NaF, KF, RbF, CsF, LiCl, NaCl, KCl, RbCl, CsCl, LiBr, NaBr, KBr, RbBr, CsBr, LiI, NaI, KI, RbI, Csl, or a combination thereof.

Examples of the alkaline earth metal halide may include at least one of BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, BaI₂, or a combination thereof.

Examples of the transition metal halide may include titanium halide (for example, TiF₄, TiCl₄, TiBr₄, TiI₄, or the like), zirconium halide (for example, ZrF₄, ZrCl₄, ZrBr₄, ZrI₄, or the like), hafnium halide (for example, HfF₄, HfCl₄, HfBr₄, Hfl₄, or the like), vanadium halide (for example, VF₃, VCl₃, VBr₃, VI₃, or the like), niobium halide (for example, NbF₃, NbCl₃, NbBr₃, NbI₃, or the like), tantalum halide (for example, TaF₃, TaCl₃, TaBr₃, Tal₃, or the like), chromium halide (for example, CrF₃, CrCl₃, CrBr₃, CrI₃, or the like), molybdenum halide (for example, MoF₃, MoCl₃, MoBr₃, MoI₃, or the like), tungsten halide (for example, WF₃, WCl₃, WBr₃, WI₃, or the like), manganese halide (for example, MnF₂, MnCl₂, MnBr₂, MnI₂, or the like), technetium halide (for example, TcF₂, TcCl₂, TcBr₂, TcI₂, or the like), rhenium halide (for example, ReF₂, ReCl₂, ReBr₂, ReI₂, or the like), iron halide (for example, FeF₂, FeCl₂, FeBr₂, FeI₂, or the like), ruthenium halide (for example, RuF₂, RuCl₂, RuBr₂, RuI₂, etc.), osmium halide (for example, OsF₂, OsCl₂, OsBr₂, OsI₂, etc.), cobalt halide (for example, CoF₂, CoCl₂, CoBr₂, CoI₂, etc.), rhodium halide (for example, RhF₂, RhCl₂, RhBr₂, RhI₂, etc.), iridium halide (for example, IrF₂, IrCl₂, IrBr₂, IrI₂, etc.), nickel halide (for example, NiF₂, NiCl₂, NiBr₂, NiI₂, or the like), palladium halide (for example, PdF₂, PdCl₂, PdBr₂, PdI₂, or the like), platinum halide (for example, PtF₂, PtCl₂, PtBr₂, PtI₂, or the like), copper halide (for example, CuF, CuCl, CuBr, CuI, or the like), silver halide (for example, AgF, AgCl, AgBr, AgI, or the like), and gold halide (for example, AuF, AuCl, AuBr, Aul, or the like).

Examples of the post-transition metal halide may include zinc halide (for example, ZnF₂, ZnCl₂, ZnBr₂, ZnI₂, or the like), indium halide (for example, InI₃, or the like), and tin halide (for example, SnI₂, or the like).

Examples of the lanthanide metal halide may include at least one of YbF, YbF₂, YbF₃, SmF₃, YbCl, YbCl₂, YbCl₃ SmCl₃, YbBr, YbBr₂, YbBr₃, SmBr₃, Ybl, YbI₂, Ybl₃, SmI₃, or a combination thereof.

Examples of the metalloid halide may include antimony halide (for example, SbCl₅, or the like).

Examples of the metal telluride may include alkali metal telluride (for example, Li₂Te, Na₂Te, K₂Te, Rb₂Te, Cs₂Te, or the like), alkaline earth metal telluride (for example, BeTe, MgTe, CaTe, SrTe, BaTe, or the like), transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, or the like), post-transition metal telluride (for example, ZnTe, or the like), and lanthanide metal telluride (for example, LaTe, CeTe, PrTe, NdTe, PmTe, EuTe, GdTe, TbTe, DyTe, HoTe, ErTe, TmTe, YbTe, LuTe, or the like).

### Emission Layer in Interlayer 130

When the light-emitting device 10 is a full-color light-emitting device, the emission layer may be patterned into a red emission layer, a green emission layer, and/or a blue emission layer, according to a sub-pixel. At least one of the emission layers may include the quantum dot as described above. In one or more embodiments, the green emission layer may be a quantum dot emission layer including the quantum dot, and the blue emission layer and the red emission layer may each be an organic emission layer each including an organic compound.

In one or more embodiments, the emission layer may have a structure in which at least two of a red emission layer, a green emission layer, and a blue emission layer may be in contact with each other or may be separated from each other. At least one emission layer of the two or more emission layers may be a quantum-dot emission layer including the quantum dot, and the remaining emission layer may be an organic emission layer including an organic compound. Other various modifications are possible.

### Electron Transport Region in Interlayer 130

The electron transport region may have: i) a single-layered structure consisting of a single layer consisting of a single material, ii) a single-layered structure consisting of a single layer consisting of a plurality of different materials, or iii) a multi-layered structure including a plurality of layers including different materials.

Also, the electron transport region may include the metal oxide layer as described above.

In one or more embodiments, the electron transport region may include, for example, ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC60BM, PC70BM, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or a combination thereof.

The electron transport region may include a buffer layer, a hole blocking layer, an electron control layer, an electron transport layer, an electron injection layer, or a combination thereof. The buffer layer, the hole blocking layer, the electron control layer, the electron transport layer, or the electron injection layer may each be the metal oxide layer, or a combination of at least one layer of the buffer layer, the hole blocking layer, the electron control layer, and the electron transport layer may be the metal oxide layer.

For example, the electron transport region may have an electron transport layer/electron injection layer structure, a hole-blocking layer/electron transport layer/electron injection layer structure, an electron control layer/electron transport layer/electron injection layer structure, or a buffer layer/electron transport layer/electron injection layer structure, the constituting layers of each structure being sequentially stacked from an emission layer.

In one or more embodiments, the electron transport region (for example, the buffer layer, the hole-blocking layer, the electron control layer, or the electron transport layer in the electron transport region) may include a metal-free compound including at least one π electron-deficient nitrogen-containing C₁-C₆₀ cyclic group.

In one or more embodiments, the electron transport region may include a compound represented by Formula 601 below:

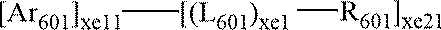

wherein, in Formula 601,
Ar₆₀₁ and L₆₀₁ may each independently be a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ are as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group that is unsubstituted or substituted with at least one R₁₀ₐ.

In one or more embodiments, when xe11 in Formula 601 is 2 or more, two or more of Ar₆₀₁(s) may be linked via a single bond.

In one or more embodiments, Ar₆₀₁ in Formula 601 may be a substituted or unsubstituted anthracene group.

In one or more embodiments, the electron transport region may include a compound represented by Formula 601-1:

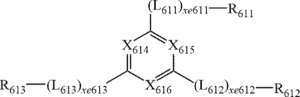

wherein, in Formula 601-1,
X₆₁₄ may be N or C(R₆₁₄), X₆₁₅ may be N or C(R₆₁₅), X₆₁₆ may be N or C(R₆₁₆), at least one of X₆₁₄ to X₆₁₆ may be N,
L₆₁₁ to L₆₁₃ are respectively as those described in connection with L₆₀₁,
xe611 to xe613 are respectively as those described in connection with xe1,
R₆₁₁ to R₆₁₃ are respectively as those described in connection with R₆₀₁, and
R₆₁₄ to R₆₁₆ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₁-C₂₀ alkylthio group, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, or a C₁-C₆₀ heteroarylthio group that is unsubstituted or substituted with at least one R₁₀ₐ.

In one or more embodiments, xe1 and xe611 to xe613 in Formulae 601 and 601-1 may each independently be 0, 1, or 2.

The electron transport region may include one of Compounds ET1 to ET45, 2,9-dimethyl-4,7-diphenyl-1,10-phenanthroline (BCP), 4,7-diphenyl-1,10-phenanthroline (Bphen), tris(8-hydroxy-quinolinato)aluminum (Alq₃), bis(2-methyl-8-quinolinolato-N1,O8)-(1,1′-biphenyl-4-olato)aluminum (BAlq), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), or a combination thereof:

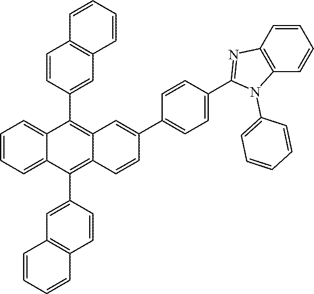 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

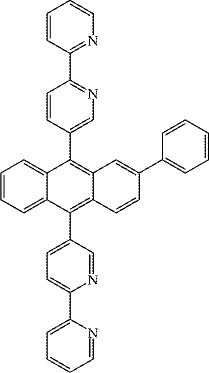 [SMILES: c1ccc(-c2ccc3c(-c4ccc(-c5ccccn5)nc4)c4ccccc4c(-c4ccc(-c5ccccn5)nc4)c3c2)cc1]

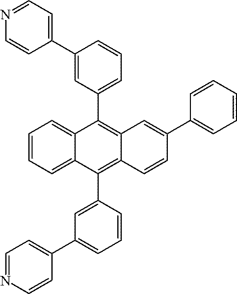 [SMILES: c1ccc(-c2ccc3c(-c4cccc(-c5ccncc5)c4)c4ccccc4c(-c4cccc(-c5ccncc5)c4)c3c2)cc1]

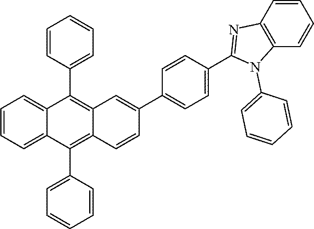 [SMILES: c1ccc(-c2c3ccccc3c(-c3ccccc3)c3cc(-c4ccc(-c5nc6ccccc6n5-c5ccccc5)cc4)ccc23)cc1]

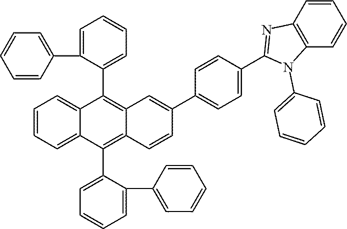 [SMILES: c1ccc(-c2ccccc2-c2c3ccccc3c(-c3ccccc3-c3ccccc3)c3cc(-c4ccc(-c5nc6ccccc6n5-c5ccccc5)cc4)ccc23)cc1]

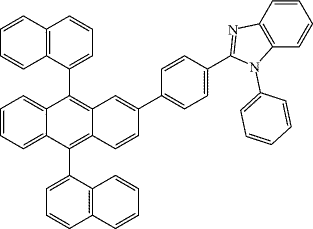 [SMILES: c1ccc(-n2c(-c3ccc(-c4ccc5c(-c6cccc7ccccc67)c6ccccc6c(-c6cccc7ccccc67)c5c4)cc3)nc3ccccc32)cc1]

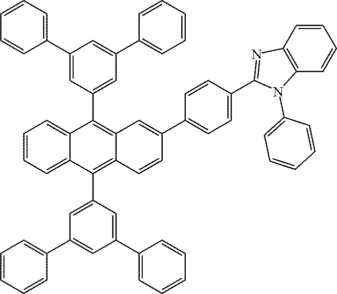 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

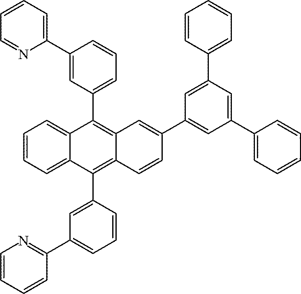 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1]

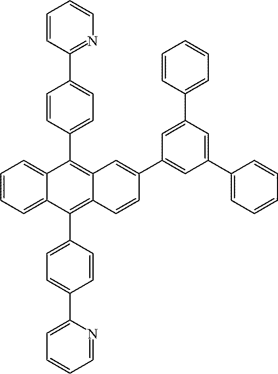 [SMILES: c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

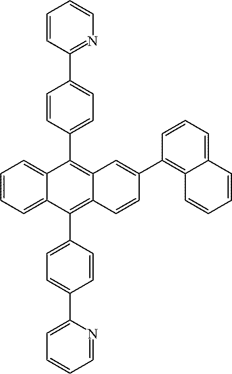 [SMILES: c1ccc(-c2ccc(-c3c4ccccc4c(-c4ccc(-c5ccccn5)cc4)c4cc(-c5cccc6ccccc56)ccc34)cc2)nc1]

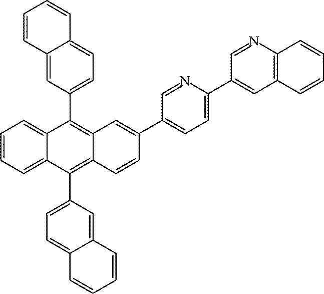 [SMILES: c1ccc2cc(-c3c4ccccc4c(-c4ccc5ccccc5c4)c4cc(-c5ccc(-c6cnc7ccccc7c6)nc5)ccc34)ccc2c1]

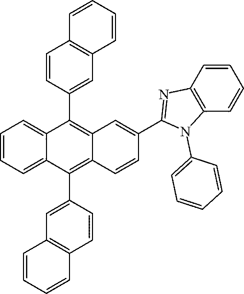 [SMILES: c1ccc(-n2c(-c3ccc4c(-c5ccc6ccccc6c5)c5ccccc5c(-c5ccc6ccccc6c5)c4c3)nc3ccccc32)cc1]

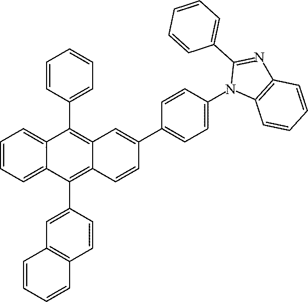 [SMILES: c1ccc(-c2c3ccccc3c(-c3ccc4ccccc4c3)c3ccc(-c4ccc(-n5c(-c6ccccc6)nc6ccccc65)cc4)cc23)cc1]

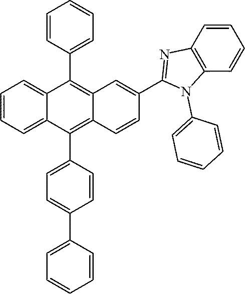 [SMILES: c1ccc(-c2ccc(-c3c4ccccc4c(-c4ccccc4)c4cc(-c5nc6ccccc6n5-c5ccccc5)ccc34)cc2)cc1]

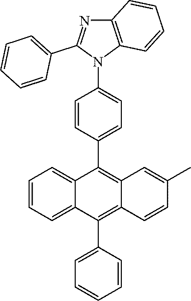 [SMILES: Cc1ccc2c(-c3ccccc3)c3ccccc3c(-c3ccc(-n4c(-c5ccccc5)nc5ccccc54)cc3)c2c1]

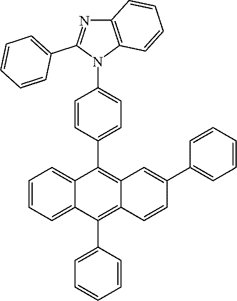 [SMILES: c1ccc(-c2ccc3c(-c4ccccc4)c4ccccc4c(-c4ccc(-n5c(-c6ccccc6)nc6ccccc65)cc4)c3c2)cc1]

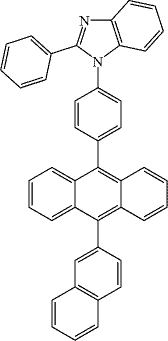 [SMILES: c1ccc(-c2nc3ccccc3n2-c2ccc(-c3c4ccccc4c(-c4ccc5ccccc5c4)c4ccccc34)cc2)cc1]

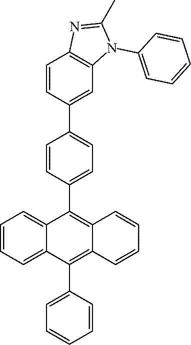 [SMILES: Cc1nc2ccc(-c3ccc(-c4c5ccccc5c(-c5ccccc5)c5ccccc45)cc3)cc2n1-c1ccccc1]

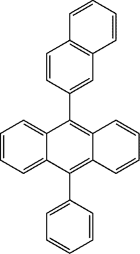 [SMILES: c1ccc(-c2c3ccccc3c(-c3ccc4ccccc4c3)c3ccccc23)cc1]

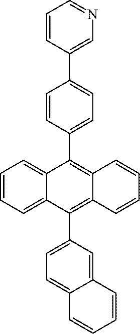 [SMILES: c1cncc(-c2ccc(-c3c4ccccc4c(-c4ccc5ccccc5c4)c4ccccc34)cc2)c1]

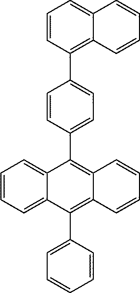 [SMILES: c1ccc(-c2c3ccccc3c(-c3ccc(-c4cccc5ccccc45)cc3)c3ccccc23)cc1]

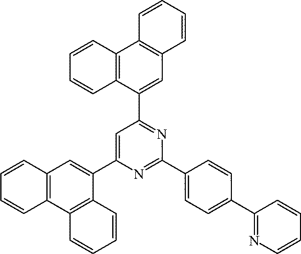 [SMILES: c1ccc(-c2ccc(-c3nc(-c4cc5ccccc5c5ccccc45)cc(-c4cc5ccccc5c5ccccc45)n3)cc2)nc1]

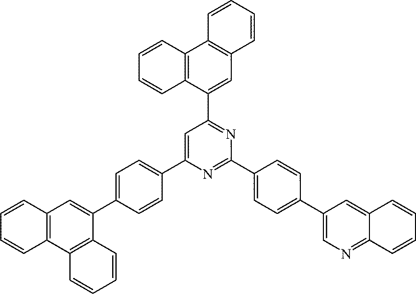 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1]

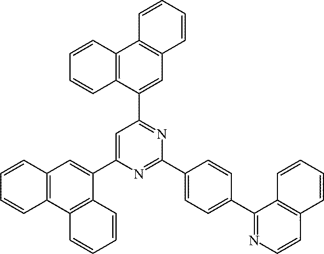 [SMILES: c1ccc2c(-c3ccc(-c4nc(-c5cc6ccccc6c6ccccc56)cc(-c5cc6ccccc6c6ccccc56)n4)cc3)nccc2c1]

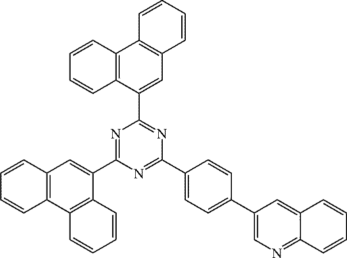 [SMILES: c1ccc2ncc(-c3ccc(-c4nc(-c5cc6ccccc6c6ccccc56)nc(-c5cc6ccccc6c6ccccc56)n4)cc3)cc2c1]

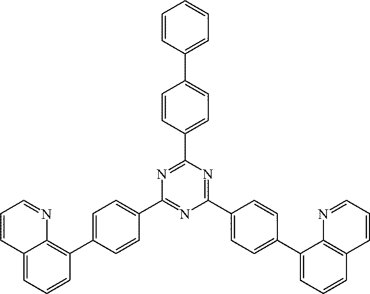 [SMILES: c1ccc(-c2ccc(-c3nc(-c4ccc(-c5cccc6cccnc56)cc4)nc(-c4ccc(-c5cccc6cccnc56)cc4)n3)cc2)cc1]

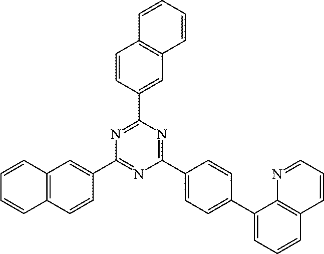 [SMILES: c1ccc2cc(-c3nc(-c4ccc(-c5cccc6cccnc56)cc4)nc(-c4ccc5ccccc5c4)n3)ccc2c1]

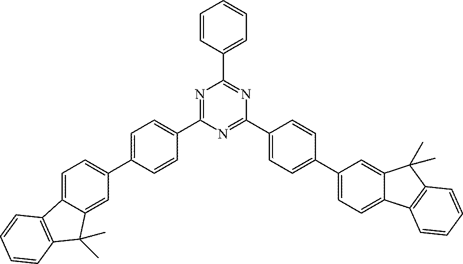 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

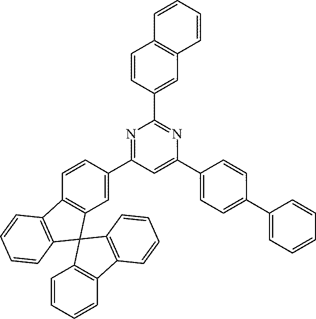 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

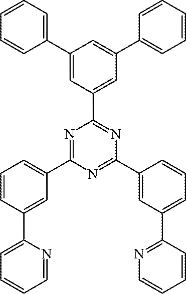 [SMILES: c1ccc(-c2cc(-c3ccccc3)cc(-c3nc(-c4cccc(-c5ccccn5)c4)nc(-c4cccc(-c5ccccn5)c4)n3)c2)cc1]

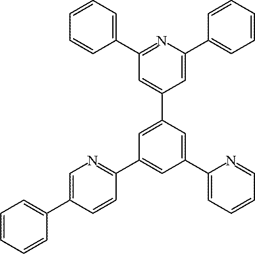 [SMILES: c1ccc(-c2ccc(-c3cc(-c4cc(-c5ccccc5)nc(-c5ccccc5)c4)cc(-c4ccccn4)c3)nc2)cc1]

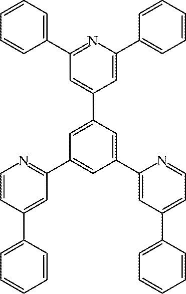 [SMILES: c1ccc(-c2ccnc(-c3cc(-c4cc(-c5ccccc5)nc(-c5ccccc5)c4)cc(-c4cc(-c5ccccc5)ccn4)c3)c2)cc1]

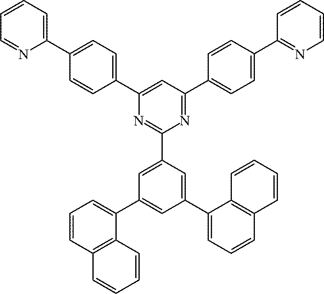 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

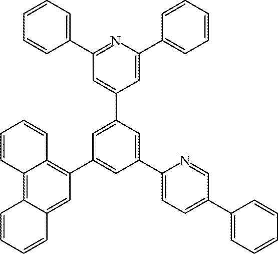 [SMILES: c1ccc(-c2ccc(-c3cc(-c4cc(-c5ccccc5)nc(-c5ccccc5)c4)cc(-c4cc5ccccc5c5ccccc45)c3)nc2)cc1]

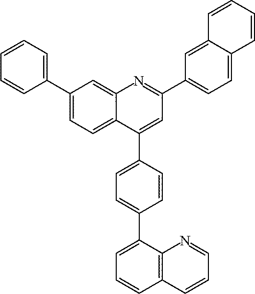 [SMILES: c1ccc(-c2ccc3c(-c4ccc(-c5cccc6cccnc56)cc4)cc(-c4ccc5ccccc5c4)nc3c2)cc1]

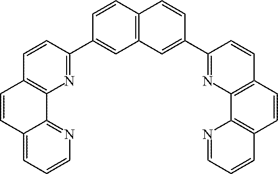 [SMILES: c1cnc2c(c1)ccc1ccc(-c3ccc4ccc(-c5ccc6ccc7cccnc7c6n5)cc4c3)nc12]

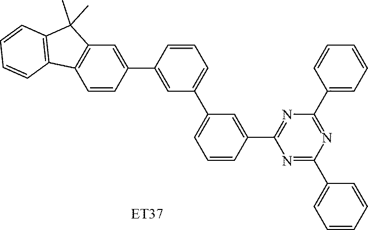

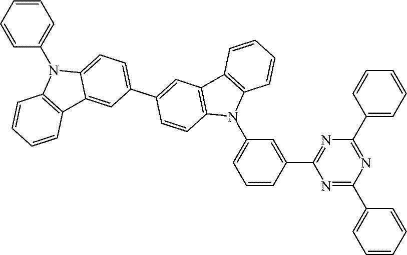 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

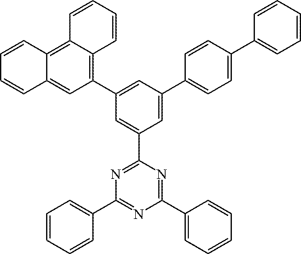 [SMILES: c1ccc(-c2ccc(-c3cc(-c4nc(-c5ccccc5)nc(-c5ccccc5)n4)cc(-c4cc5ccccc5c5ccccc45)c3)cc2)cc1]

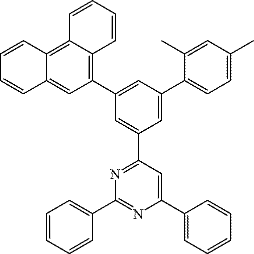 [SMILES: Cc1ccc(-c2cc(-c3cc(-c4ccccc4)nc(-c4ccccc4)n3)cc(-c3cc4ccccc4c4ccccc34)c2)c(C)c1]

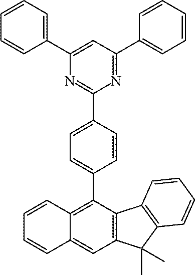 [SMILES: CC1(C)c2ccccc2-c2c1cc1ccccc1c2-c1ccc(-c2nc(-c3ccccc3)cc(-c3ccccc3)n2)cc1]

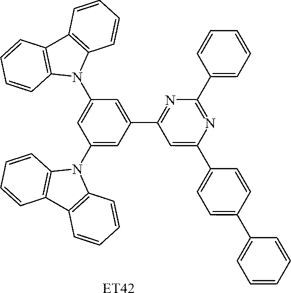

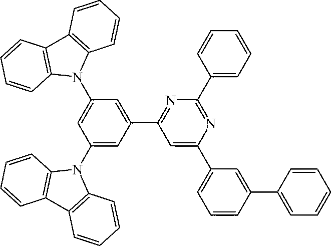 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

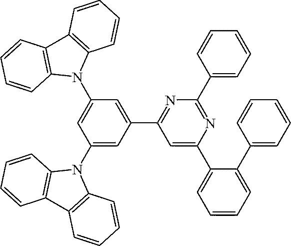 [SMILES: c1ccc(-c2nc(-c3cc(-n4c5ccccc5c5ccccc54)cc(-n4c5ccccc5c5ccccc54)c3)cc(-c3ccccc3-c3ccccc3)n2)cc1]

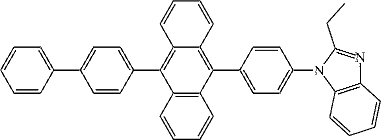 [SMILES: CCc1nc2ccccc2n1-c1ccc(-c2c3ccccc3c(-c3ccc(-c4ccccc4)cc3)c3ccccc23)cc1]

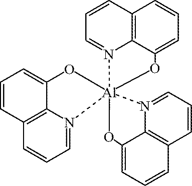

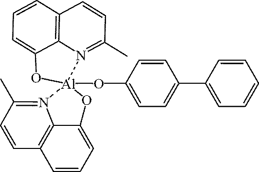

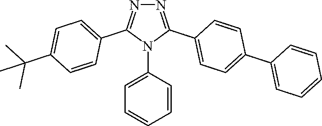 [SMILES: CC(C)(C)c1ccc(-c2nnc(-c3ccc(-c4ccccc4)cc3)n2-c2ccccc2)cc1]

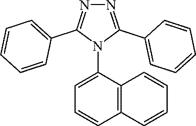 [SMILES: c1ccc(-c2nnc(-c3ccccc3)n2-c2cccc3ccccc23)cc1]

A thickness of the electron transport region may be from about 100 Å to about 5,000 Å, for example, about 160 Å to about 4,000 Å. When the electron transport region includes a buffer layer, a hole blocking layer, an electron control layer, an electron transport layer, or a combination thereof, the thickness of the buffer layer, the hole blocking layer, or the electron control layer may each independently be from about 20 Å to about 1000 Å, for example, about 30 Å to about 300 Å, and the thickness of the electron transport layer may be from about 100 Å to about 1,000 Å, for example, about 150 Å to about 500 Å. When the thickness of the buffer layer, the hole blocking layer, the electron control layer, the electron transport layer, and/or the electron transport region are within these ranges, satisfactory electron transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth metal complex, or a combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or a combination thereof.

In one or more embodiments, the metal-containing material may include a Li complex. The Li complex may include, for example, Compound ET-D1 (LiQ) or ET-D2:

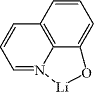

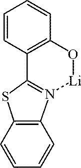

The electron transport region may include an electron injection layer that facilitates the injection of electrons from the second electrode 150. The electron injection layer may be in direct contact with the second electrode 150.

The electron injection layer may have: i) a single-layered structure consisting of a single layer consisting of a single material, ii) a single-layered structure consisting of a single layer consisting of a plurality of different materials, or iii) a multi-layered structure including a plurality of layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a combination thereof.

The alkali metal may include Li, Na, K, Rb, Cs, or a combination thereof. The alkaline earth metal may include Mg, Ca, Sr, Ba, or a combination thereof. The rare earth metal may include Sc, Y, Ce, Tb, Yb, Gd, or a combination thereof.

The alkali metal-containing compound, the alkaline earth metal-containing compound, and the rare earth metal-containing compound may include oxides, halides (for example, fluorides, chlorides, bromides, or iodides), or tellurides of the alkali metal, the alkaline earth metal, and the rare earth metal, or a combination thereof.

The alkali metal-containing compound may include alkali metal oxides, such as Li₂O, Cs₂O, or K₂O, alkali metal halides, such as LiF, NaF, CsF, KF, Lil, Nal, Csl, or KI, or a combination thereof. The alkaline earth metal-containing compound may include an alkaline earth metal compound, such as BaO, SrO, CaO, BaₓSr₁₋ₓO (x is a real number satisfying the condition of 0<x<1), BaₓCa₁₋ₓO (x is a real number satisfying the condition of 0<x<1), or the like. The rare earth metal-containing compound may include at least one of YbF₃, ScF₃, Sc₂O₃, Y₂O₃, Ce₂O₃, GdF₃, TbF₃, YbI₃, ScI₃, TbI₃, or a combination thereof. In one or more embodiments, the rare earth metal-containing compound may include lanthanide metal telluride. Examples of the lanthanide metal telluride may include at least one of LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, or a combination thereof.

The alkali metal complex, the alkaline earth-metal complex, and the rare earth metal complex may include i) one of ions of the alkali metal, the alkaline earth metal, and the rare earth metal and ii), as a ligand bonded to the metal ion, for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or a combination thereof.

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a combination thereof, as described above. In one or more embodiments, the electron injection layer may further include an organic material (for example, a compound represented by Formula 601).

In one or more embodiments, the electron injection layer may consist of i) an alkali metal-containing compound (for example, an alkali metal halide), ii) a) an alkali metal-containing compound (for example, an alkali metal halide); and b) an alkali metal, an alkaline earth metal, a rare earth metal, or a combination thereof. In one or more embodiments, the electron injection layer may be a KI:Yb co-deposited layer, a RbI:Yb co-deposited layer, a LiF:Yb co-deposited layer, etc.

When the electron injection layer further includes an organic material, alkali metal, alkaline earth metal, rare earth metal, an alkali metal-containing compound, an alkaline earth metal-containing compound, a rare earth metal-containing compound, alkali metal complex, alkaline earth-metal complex, rare earth metal complex, or a combination thereof may be homogeneously or non-homogeneously dispersed in a matrix including the organic material.

A thickness of the electron injection layer may be in a range of about 1 Å to about 100 Å, and, for example, about 3 Å to about 90 Å. When the thickness of the electron injection layer is within the range described above, satisfactory electron injection characteristics may be obtained without a substantial increase in driving voltage.

### Second Electrode 150

The second electrode 150 may be located on the interlayer 130 having such a structure. The second electrode 150 may be a cathode, which is an electron injection electrode, and as the material for the second electrode 150, a metal, an alloy, an electrically conductive compound, or a combination thereof, each having a low work function, may be used.

In one or more embodiments, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or a combination thereof. The second electrode 150 may be a transmissive electrode, a semi-transmissive electrode, or a reflective electrode.

The second electrode 150 may have a single-layered structure or a multi-layered structure including two or more layers.

### Capping Layer

A first capping layer may be located outside the first electrode 110, and/or a second capping layer may be located outside the second electrode 150. In detail, the light-emitting device 10 may have a structure in which the first capping layer, the first electrode 110, the interlayer 130, and the second electrode 150 are sequentially stacked in this stated order, a structure in which the first electrode 110, the interlayer 130, the second electrode 150, and the second capping layer are sequentially stacked in this stated order, or a structure in which the first capping layer, the first electrode 110, the interlayer 130, the second electrode 150, and the second capping layer are sequentially stacked in this stated order.

Light generated in an emission layer of the interlayer 130 of the light-emitting device 10 may be extracted toward the outside through the first electrode 110, which is a semi-transmissive electrode or a transmissive electrode, and the first capping layer or light generated in an emission layer of the interlayer 130 of the light-emitting device 10 may be extracted toward the outside through the second electrode 150, which is a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 is increased, so that the emission efficiency of the light-emitting device 10 may be improved.

Each of the first capping layer and second capping layer may include a material having a refractive index (at 589 nm) of 1.6 or more.

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include carbocyclic compounds, heterocyclic compounds, amine group-containing compounds, porphyrin derivatives, phthalocyanine derivatives, naphthalocyanine derivatives, alkali metal complexes, alkaline earth metal complexes, or a combination thereof. The carbocyclic compound, the heterocyclic compound, and the amine group-containing compound may be optionally substituted with a substituent containing at least one of O, N, S, Se, Si, F, Cl, Br, I, or a combination thereof.

In one or more embodiments, at least one of the first capping layer and the second capping layer may each independently include an amine group-containing compound.

In one or more embodiments, at least one of the first capping layer and the second capping layer may each independently include a compound represented by Formula 201, a compound represented by Formula 202, or a combination thereof.

In one or more embodiments, at least one of the first capping layer and the second capping layer may each independently include one of Compounds HT28 to HT33, one of Compounds CP1 to CP6, β-NPB, or a combination thereof:

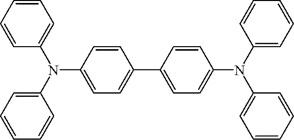 [SMILES: c1ccc(N(c2ccccc2)c2ccc(-c3ccc(N(c4ccccc4)c4ccccc4)cc3)cc2)cc1]

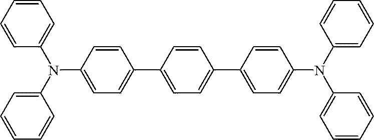 [SMILES: c1ccc(N(c2ccccc2)c2ccc(-c3ccc(-c4ccc(N(c5ccccc5)c5ccccc5)cc4)cc3)cc2)cc1]

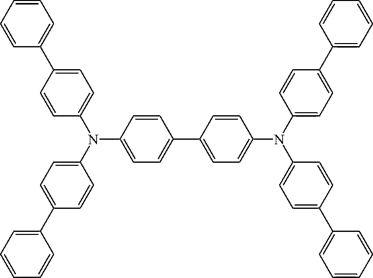 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

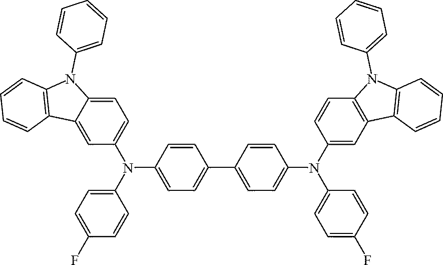 [SMILES: Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

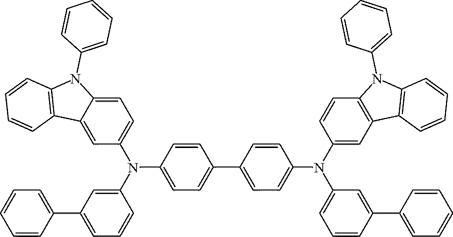 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

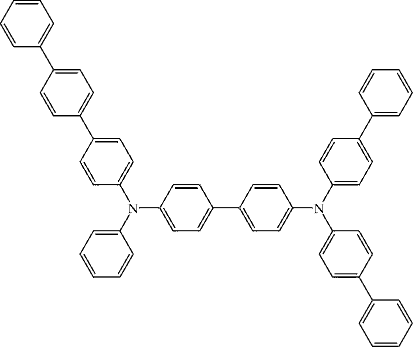 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

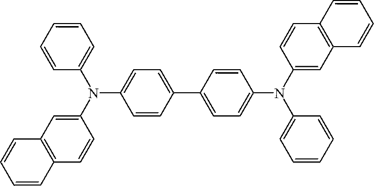 [SMILES: c1ccc(N(c2ccc(-c3ccc(N(c4ccccc4)c4ccc5ccccc5c4)cc3)cc2)c2ccc3ccccc3c2)cc1]

### Film

The first compound represented by Formula 1 may be included in various films. Accordingly, according to one or more embodiments, a film including the first compound represented by Formula 1 may be provided. The film may be, for example, an optical member (or a light control means) (for example, a color filter, a color conversion member, a capping layer, a light extraction efficiency enhancement layer, a selective light absorbing layer, a polarizing layer, a quantum dot-containing layer, or like), a light-blocking member (for example, a light reflective layer, a light absorbing layer, or the like), a protective member (for example, an insulating layer, a dielectric layer, or the like).

### Electronic Apparatus

The light-emitting device may be included in various electronic apparatuses. In one or more embodiments, the electronic apparatus including the light-emitting device may be a light-emitting apparatus, an authentication apparatus, or the like.

The electronic apparatus (for example, light-emitting apparatus) may further include, in addition to the light-emitting device, i) a color filter, ii) a color conversion layer, or iii) a color filter and a color conversion layer. The color filter and/or the color conversion layer may be located in at least one traveling direction of light emitted from the light-emitting device. For example, the light emitted from the light-emitting device may be blue light or white light. The light-emitting device may be similar to or the same as described above. In one or more embodiments, the color conversion layer may include quantum dots. The quantum dot may be, for example, a quantum dot as described herein.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining layer may be located among the subpixel areas to define each of the subpixel areas.

The color filter may further include a plurality of color filter areas and light-shielding patterns located among the color filter areas, and the color conversion layer may include a plurality of color conversion areas and light-shielding patterns located among the color conversion areas.

The color filter areas (or the color conversion areas) may include a first area emitting first color light, a second area emitting second color light, and/or a third area emitting third color light, and the first color light, the second color light, and/or the third color light may have different maximum emission wavelengths from one another. In one or more embodiments, the first color light may be red light, the second color light may be green light, and the third color light may be blue light. In one or more embodiments, the color filter areas (or the color conversion areas) may include quantum dots. In detail, the first area may include a red quantum dot, the second area may include a green quantum dot, and the third area may not include a quantum dot. The quantum dot is the same as described in the present specification. The first area, the second area, and/or the third area may each further include a scatterer.

In one or more embodiments, the light-emitting device may emit first light, the first area may absorb the first light to emit first first-color light, the second area may absorb the first light to emit second first-color light, and the third area may absorb the first light to emit third first-color light. In this regard, the first first-color light, the second first-color light, and the third first-color light may have different maximum emission wavelengths. In detail, the first light may be blue light, the first first-color light may be red light, the second first-color light may be green light, and the third first-color light may be blue light.

The electronic apparatus may further include a thin-film transistor in addition to the light-emitting device as described above. The thin-film transistor may include a source electrode, a drain electrode, and an activation layer, wherein any one of the source electrode and the drain electrode may be electrically connected to any one of the first electrode and the second electrode of the light-emitting device.

The thin-film transistor may further include a gate electrode, a gate insulating film, etc.

The activation layer may include crystalline silicon, amorphous silicon, organic semiconductor, oxide semiconductor, or the like.

The electronic apparatus may further include a sealing portion for sealing the light-emitting device. The sealing portion and/or the color conversion layer may be located between the color filter and the light-emitting device. The sealing portion allows light from the light-emitting device to be extracted to the outside, while simultaneously preventing ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin film encapsulation layer, the electronic apparatus may be flexible.

Various functional layers may be additionally located on the sealing portion, in addition to the color filter and/or the color conversion layer, according to the use of the electronic apparatus. The functional layers may include a touch screen layer, a polarizing layer, and the like. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (for example, fingertips, pupils, or the like).

The authentication apparatus may further include, in addition to the light-emitting device, a biometric information collector.

The electronic apparatus may be applied to various displays, light sources, lighting, personal computers (for example, a mobile personal computer), mobile phones, digital cameras, electronic diaries, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, or the like.

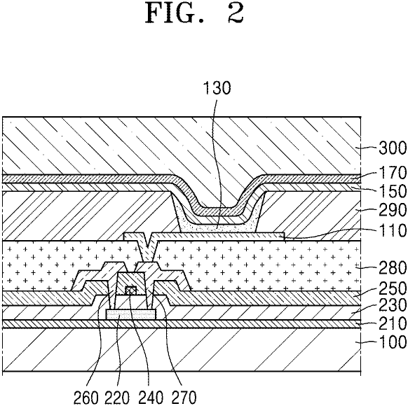

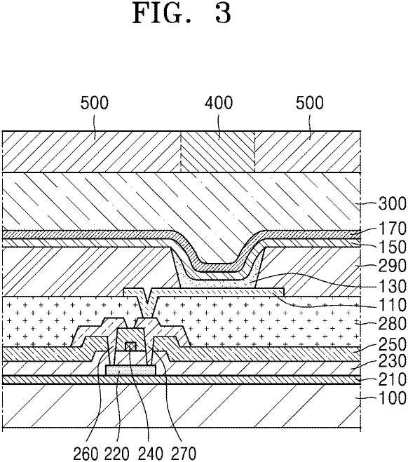

### Description of FIGS. 2 and 3

FIG. 2 is a cross-sectional view of a light-emitting apparatus according to one or more embodiments.

The light-emitting apparatus of FIG. 2 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be formed on the substrate 100. The buffer layer 210 may prevent penetration of impurities through the substrate 100 and may provide a flat surface on the substrate 100.

A TFT may be located on the buffer layer 210. The TFT may include an activation layer 220, a gate electrode 240, a source electrode 260, and a drain electrode 270.

The activation layer 220 may include an inorganic semiconductor such as silicon or polysilicon, an organic semiconductor, or an oxide semiconductor, and may include a source region, a drain region and a channel region.

A gate insulating film 230 for insulating the activation layer 220 from the gate electrode 240 may be located on the activation layer 220, and the gate electrode 240 may be located on the gate insulating film 230.

An interlayer insulating film 250 is located on the gate electrode 240. The interlayer insulating film 250 may be placed between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be located on the interlayer insulating film 250. The interlayer insulating film 250 and the gate insulating film 230 may be formed to expose the source region and the drain region of the activation layer 220, and the source electrode 260 and the drain electrode 270 may be in contact with the exposed portions of the source region and the drain region of the activation layer 220.

The TFT is electrically connected to a light-emitting device to drive the light-emitting device, and is covered by a passivation layer 280. The passivation layer 280 may include an inorganic insulating film, an organic insulating film, or a combination thereof. A light-emitting device is provided on the passivation layer 280. The light-emitting device may include a first electrode 110, an interlayer 130, and a second electrode 150.

The first electrode 110 may be formed on the passivation layer 280. The passivation layer 280 does not completely cover the drain electrode 270 and exposes a portion of the drain electrode 270, and the first electrode 110 is connected to the exposed portion of the drain electrode 270.

A pixel-defining layer 290 containing an insulating material may be located on the first electrode 110. The pixel-defining layer 290 exposes a region of the first electrode 110, and an interlayer 130 may be formed in the exposed region of the first electrode 110. The pixel-defining layer 290 may be a polyimide or polyacrylic organic film. Although not shown in FIG. 2, at least some layers of the interlayer 130 may extend beyond the upper portion of the pixel-defining layer 290 to be located in the form of a common layer.

The second electrode 150 may be located on the interlayer 130, and a capping layer 170 may be additionally formed on the second electrode 150. The capping layer 170 may be formed to cover the second electrode 150.

The encapsulation portion 300 may be located on the capping layer 170. The encapsulation portion 300 may be located on a light-emitting device to protect the light-emitting device from moisture or oxygen. The encapsulation portion 300 may include: an inorganic film including a silicon nitride (SiNₓ), a silicon oxide (SiOₓ), indium tin oxide, indium zinc oxide, or a combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, or the like), an epoxy-based resin (for example, aliphatic glycidyl ether (AGE), or the like), or a combination thereof; or a combination of the inorganic film and the organic film.

FIG. 3 is a cross-sectional view of a light-emitting apparatus according to one or more embodiments.

The light-emitting apparatus of FIG. 3 is similarto the light-emitting apparatus of FIG. 2, except that a light-shielding pattern 500 and a functional region 400 are additionally located on the encapsulation portion 300. The functional region 400 may be a combination of i) a color filter area, ii) a color conversion area, or iii) a combination of the color filter area and the color conversion area. In one or more embodiments, the light-emitting device included in the light-emitting apparatus of FIG. 3 may be a tandem light-emitting device.

### [Manufacture Method]

Respective layers included in the hole transport region, the emission layer, and respective layers included in the electron transport region may be formed in a certain region by using one or more suitable methods selected from vacuum deposition, spin coating, casting, Langmuir-Blodgett (LB) deposition, ink-jet printing, laser-printing, and/or laser-induced thermal imaging.

When layers constituting the hole transport region, an emission layer, and layers constituting the electron transport region are formed by vacuum deposition, the deposition may be performed at a deposition temperature of about 100° C. to about 500° C., a vacuum degree of about 10⁻⁸ torr to about 10⁻³ torr, and a deposition speed of about 0.01 angstroms per second (Å/sec) to about 100 Å/sec, depending on a material to be included in a layer to be formed and the structure of a layer to be formed.

### Definition of Terms

The term “C₃-C₆₀ carbocyclic group” as used herein refers to a cyclic group consisting of carbon only as a ring-forming atom and having three to sixty carbon atoms, and the term “C₁-C₆₀ heterocyclic group” as used herein refers to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. In one or more embodiments, the C₁-C₆₀ heterocyclic group has 3 to 61 ring-forming atoms.

The “cyclic group” as used herein may include the C₃-C₆₀ carbocyclic group and the C₁-C₆₀ heterocyclic group.

The term “π electron-rich C₃-C₆₀ cyclic group” as used herein refers to a cyclic group that has three to sixty carbon atoms and does not include *—N═*’ as a ring-forming moiety, and the term “π electron-deficient nitrogen-containing C₁-C₆₀ cyclic group” as used herein refers to a heterocyclic group that has one to sixty carbon atoms and includes *—N═*’ as a ring-forming moiety.

In one or more embodiments,
the C₃-C₆₀ carbocyclic group may be i) group T1 or ii) a condensed cyclic group in which two or more groups T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) group T2, ii) a condensed cyclic group in which two or more groups T2 are condensed with each other, or iii) a condensed cyclic group in which at least one group T2 and at least one group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
the π electron-rich C₃-C₆₀ cyclic group may be i) group T1, ii) a condensed cyclic group in which two or more groups T1 are condensed with each other, iii) group T3, iv) a condensed cyclic group in which two or more groups T3 are condensed with each other, or v) a condensed cyclic group in which at least one group T3 and at least one group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),
the π electron-deficient nitrogen-containing C₁-C₆₀ cyclic group may be i) group T4, ii) a condensed cyclic group in which two or more group T4 are condensed with each other, iii) a condensed cyclic group in which at least one group T4 and at least one group T1 are condensed with each other, iv) a condensed cyclic group in which at least one group T4 and at least one group T3 are condensed with each other, or v) a condensed cyclic group in which at least one group T4, at least one group T1, and at least one group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,
group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
group T3 may be a furan group, a thiophene group, a 1 H-pyrrole group, a silole group, or a borole group, and
group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The term “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” as used herein refers to a group condensed to any cyclic group or a polyvalent group (for example, a divalent group, a trivalent group, a tetravalent group, etc.), depending on the structure of a formula in connection with which the terms are used. In one or more embodiments, “a benzene group” may be a benzo group, a phenyl group, a phenylene group, or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and examples of the divalent C₃-C₆₀ carbocyclic group and the monovalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as used herein refers to a linear or branched aliphatic hydrocarbon monovalent group that has one to sixty carbon atoms, and examples thereof include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein refers to a divalent group having the same structure as the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof include an ethynyl group and a propynyl group. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by -OA₁₀₁ (wherein A₁₀₁ is the C₁-C₆₀ alkyl group), and examples thereof include a methoxy group, an ethoxy group, and an isopropyloxy group.

The term “C₁-C₆₀ alkylthio group” used herein refers to a monovalent group represented by -SA_{101′} (wherein A_{101′} is the C₁-C₆₀ alkyl group).

The term “C₃-C₁₀ cycloalkyl group” as used herein refers to a monovalent saturated hydrocarbon cyclic group having 3 to 10 carbon atoms, and examples thereof include a cyclopropyl group, a cyclobutyl group, a cyclopentyl group, a cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group that further includes, in addition to a carbon atom, at least one heteroatom as a ring-forming atom and has 1 to 10 carbon atoms, and examples thereof include a 1,2,3,4-oxatriazolidinyl group, a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” used herein refers to a monovalent cyclic group that has three to ten carbon atoms and at least one carbon-carbon double bond in the ring thereof and no aromaticity, and examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group that has, in addition to a carbon atom, at least one heteroatom as a ring-forming atom, 1 to 10 carbon atoms, and at least one carbon-carbon double bond in the cyclic structure thereof. Examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having six to sixty carbon atoms, and the term “C₆-C₆₀ arylene group” as used herein refers to a divalent group having a carbocyclic aromatic system having six to sixty carbon atoms. Examples of the C₆-C₆₀ aryl group include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the rings may be condensed with each other.

The term “C₁-C₆₀ heteroaryl group” as used herein refers to a monovalent group having a heterocyclic aromatic system that has, in addition to a carbon atom, at least one heteroatom as a ring-forming atom, and 1 to 60 carbon atoms. The term “C₁-C₆₀ heteroarylene group” as used herein refers to a divalent group having a heterocyclic aromatic system that has, in addition to a carbon atom, at least one heteroatom as a ring-forming atom, and 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the rings may be condensed with each other.

The term “monovalent non-aromatic condensed polycyclic group” as used herein refers to a monovalent group having two or more rings condensed to each other, only carbon atoms (for example, having 8 to 60 carbon atoms) as ring-forming atoms, and non-aromaticity in its molecular structure when considered as a whole. Examples of the monovalent non-aromatic condensed polycyclic group include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein refers to a divalent group having the same structure as a monovalent non-aromatic condensed polycyclic group.

The term “monovalent non-aromatic condensed heteropolycyclic group” as used herein refers to a monovalent group having two or more rings condensed to each other, at least one heteroatom other than carbon atoms (for example, having 1 to 60 carbon atoms), as a ring-forming atom, and non-aromaticity in its molecular structure when considered as a whole. Examples of the monovalent non-aromatic condensed heteropolycyclic group include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein refers to a divalent group having the same structure as a monovalent non-aromatic condensed heteropolycyclic group.

The term “C₆-C₆₀ aryloxy group” as used herein indicates -OA₁₀₂ (wherein A₁₀₂ is the C₆-C₆₀ aryl group), and the term “C₆-C₆₀ arylthio group” as used herein indicates -SA₁₀₃ (wherein A₁₀₃ is the C₆-C₆₀ aryl group).

The term “C₁-C₆₀ heteroaryloxy group” as used herein indicates -OA₁₀₄ (wherein A₁₀₄ is a C₁-C₆₀ heteroaryl group), and the term “C₁-C₆₀ heteroarylthio group” as used herein indicates -SA₁₀₅ (wherein A₁₀₅ is the C₁-C₆₀ heteroaryl group).

The term “C₇-C₆₀ aryl alkyl group” used herein refers to -A₁₀₄A₁₀₅ (where A₁₀₄ may be a C₁-C₅₄ alkylene group, and A₁₀₅ may be a C₆-C₅₉ aryl group), and the term “C₂-C₆₀ heteroaryl alkyl group” used herein refers to -A₁₀₆A₁₀₇(where A₁₀₆ may be a C₁-C₅₉ alkylene group, and A₁₀₇ may be a C₁-C₅₉ heteroaryl group).

The term “C₇-C₆₀ alkyl aryl group” used herein refers to -A₁₀₅A₁₀₄ (where A₁₀₄ may be a C₁-C₅₄ alkylene group, and A₁₀₅ may be a C₆-C₅₉ aryl group), and the term “C₂-C₆₀ alkyl heteroaryl group” used herein refers to -A₁₀₇A₁₀₆(where A₁₀₆ may be a C₁-C₅₉ alkylene group, and A₁₀₇ may be a C₁-C₅₉ heteroaryl group).

R₁₀ₐ may be:
deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, or a phosphoric acid group or a salt thereof;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each unsubstituted or substituted with deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ aryl alkyl group, or a C₂-C₆₀ heteroaryl alkyl group, each unsubstituted or substituted with deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃, and Q₃₁ to Q₃₃ as used herein may each independently be: hydrogen, deuterium, —F, —Cl, —Br, —I, —SF₅, a hydroxyl group, a cyano group, a nitro group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₆₀ carbocyclic group, a substituted or unsubstituted C₁-C₆₀ heterocyclic group, a substituted or unsubstituted C₇-C₆₀ alkyl aryl group, a substituted or unsubstituted C₇₋C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, or a substituted or unsubstituted C₁-C₆₀ heteroaryloxy group.

The term “hetero atom” as used herein refers to any atom other than a carbon atom. Examples of the heteroatom include O, S, N, P, Si, B, Ge, Se, or a combination thereof.

“Ph” as used herein refers to a phenyl group, “Me” as used herein refers to a methyl group, “Et” as used herein refers to an ethyl group, “tert-Bu” or “Bu^{t}” as used herein refers to a tert-butyl group, and “OMe” as used herein refers to a methoxy group.

The term “biphenyl group” as used herein refers to “a phenyl group substituted with a phenyl group.” In other words, the “biphenyl group” is a substituted phenyl group having a C₆-C₆₀ aryl group as a substituent.

The term “terphenyl group” as used herein refers to “a phenyl group substituted with a biphenyl group”. The “terphenyl group” is a substituted phenyl group having, as a substituent, a C₆-C₆₀ aryl group substituted with a C₆-C₆₀ aryl group.

* and *’ as used herein, unless defined otherwise, each refer to a binding site to a neighboring atom in a corresponding formula or moiety.

Hereinafter, embodiments of a compound and light-emitting device will be described in further detail with reference to the following examples.

### EXAMPLES

### Evaluation Example 1

A boiling point (b.p., °C), viscosity (cP), and surface tension (dyn/cm) of each of Compounds 1 to 8 and Comparative Compounds 1 and 2 were measured, and results thereof are shown in Table 1 below. In this regard, the boiling point was measured by using Duran’s boiling point specification device, the viscosity was measured by using Brookfield’s DV2T, and the surface tension was measured by using Data Physics DCTA21.

TABLE 1

| Solvent | b.p.(°C) | Viscosity (cp) | Surface tension (dyn/cm) |
|---|---|---|---|
| Compound 1 | 224 | 6.2 | 28.2 |
| Compound 2 | 220 | 6.0 | 28.0 |
| Compound 3 | 271 | 7.8 | 30.9 |
| Compound 4 | 264 | 7.6 | 30.6 |
| Compound 5 | 245 | 6.5 | 29.2 |
| Compound 6 | 311 | 10.2 | 38.6 |
| Compound 7 | 460 | 15.4 | 38.5 |
| Compound 8 | 256 | 8.5 | 37.4 |
| Comparative Compound 1 | 78 | 1.1 | 21.1 |
| Comparative Compound 2 | 230 | 5.1 | 29.6 |

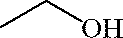

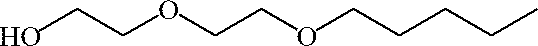

### Preparation Examples 1 to 8, Comparative Preparation Examples 1 and 2

As described in Table 2 below, Compositions 1 to 8 and Comparative Compositions 1 and 2, each including a metal oxide and a solvent, were prepared.

TABLE 2

| | | | |
|---|---|---|---|
| Composition | Metal oxide | Solvent | Amount of metal oxide (weight ratio based on solvent) |
| Composition 1 | ZnMgO | Compound 1 | 3 wt% |
| Composition 2 | ZnMgO | Compound 2 | 3 wt% |
| Composition 3 | ZnMgO | Compound 3 | 3 wt% |
| Composition 4 | ZnMgO | Compound 4 | 3 wt% |
| Composition 5 | ZnMgO | Compound 5 | 3 wt% |
| Composition 6 | ZnMgO | Compound 6 | 3 wt% |
| Composition 7 | ZnMgO | Compound 7 | 3 wt% |
| Composition 8 | ZnMgO | Compound 8 | 3 wt% |
| Comparative Composition 1 | ZnMgO | Comparative Compound 1 | 3 wt% |
| Comparative Composition 2 | ZnMgO | Comparative Compound 2 | 3 wt% |

### Evaluation Example 2

Compositions according to Preparation Examples 1 to 8 and Comparative Preparation Examples 1 and 2 were left at room temperature, and after one week, the particle size of each of the compositions was measured. The particle size was measured by using DLS equipment (Malvern’s Nano-ZS90). The smaller the difference between the initial average particle size and the average particle size after one week, the better the dispersibility of the solvent used.

TABLE 3

| Composition | Initial average particle size (nm) | Particle size (nm) after one week |
|---|---|---|
| Composition 1 | 22 | 24 |
| Composition 2 | 21 | 20 |
| Composition 3 | 24 | 23 |
| Composition 4 | 19 | 28 |
| Composition 5 | 20 | 27 |
| Composition 6 | 22 | 25 |
| Composition 7 | 23 | 29 |
| Composition 8 | 20 | 26 |
| Comparative Composition 1 | 18 | 490 |
| Comparative Composition 2 | 20 | 22 |

From Table 3, it was confirmed that Compositions 1 to 8 each had a smaller difference between the initial average particle size and the average particle size after one week than that of Comparative Composition 1. Therefore, it was confirmed that Compounds 1 to 8 used as solvents in Compositions 1 to 8 had excellent dispersibility.

### Evaluation Example 3

Compositions according to Preparation Examples 1 to 8 and Comparative Preparation Examples 1 and 2 were discharged in an inkjet facility, and then after 24 hours, the dischargeability thereof was confirmed. The dischargeability standard is ±20 µm of impact accuracy, and the Dimatix Materials Printer DMP-2850 was used as the inkjet facility.

TABLE 4

| | | | |
|---|---|---|---|
| | Composition | Initial dischargeability | Dischargeability after 24 hours |
| Example 3-1 | Composition 1 | O | O |
| Example 3-2 | Composition 2 | O | O |
| Example 3-3 | Composition 3 | O | O |
| Example 3-4 | Composition 4 | O | O |
| Example 3-5 | Composition 5 | O | O |
| Example 3-6 | Composition 6 | O | O |
| Example 3-7 | Composition 7 | O | O |
| Example 3-8 | Composition 8 | O | O |
| Comparative Example 3-1 | Comparative Composition 1 | O | X |
| Comparative Example 3-2 | Comparative Composition 2 | O | O |

From table 4, it was confirmed that Compositions 1 to 8 were suitable for an inkjet process.

### Examples 1-1 to 1-8 and Comparative Examples 1-1 and 1-2

InP red quantum dot ink (solvent: octane, solid: 0.7 wt%) was spin-coated on a glass substrate (50 × 50 millimeters (mm)) to form a layer having a thickness of 20 nm, followed by baking at 100° C. for 10 minutes. Afterwards, each solvent described in Table 5 below was spin-coated on the layer, followed by baking at 100° C. for 10 minutes.

### Evaluation Example 4

The PL intensity of a layer formed by spin-coating InP red quantum dot ink was measured and a value thereof is calculated as 100, and the PL intensity of the layer was measured by spin-coating each solvent described in Table 5 below on the layer and then baking at 100° C. for 10 minutes. Values thereof are described in Table 5 below.

(PL measurement facility: Varian’s Cary Eclipse Fluorescence Spectrophotometer)

TABLE 5

| | Solvent | PL Intensity |
|---|---|---|
| Example 1-1 | Compound 1 | 82 |
| Example 1-2 | Compound 2 | 78 |
| Example 1-3 | Compound 3 | 86 |
| Example 1-4 | Compound 4 | 79 |
| Example 1-5 | Compound 5 | 77 |
| Example 1-6 | Compound 6 | 84 |
| Example 1-7 | Compound 7 | 86 |
| Example 1-8 | Compound 8 | 79 |
| Comparative Example 1-1 | Comparative Compound 1 | 90 |
| Comparative Example 1-2 | Comparative Compound 2 | 51 |

From Table 5, it was confirmed that the thin layer according to each of Examples 1-1 to 1-8 had improved PL intensity, as compared to the thin layer according to Comparative Example 1-2.

### Example 2-1

An ITO glass substrate (50 × 50 mm, 15 ohms per meter (Ω/m)) (Samsung-Corning), which is an EL-QD glass substrate, was subjected to ultrasonic cleaning sequentially using distilled water and isopropanol, followed by UV ozone cleaning for 30 minutes. PEDOT:PSS (Clevios TM HIL8) was spin-coated on the glass substrate with a transparent electrode line attached thereon after cleaning to form a layer having a thickness of 60 nm, followed by baking at 120° C. for 10 minutes, thereby forming a hole injection layer. Compound 1 was spin-coated on the hole injection layer to form a layer having a thickness of 20 nm, followed by baking at 120° C. for 10 minutes, thereby forming a hole transport layer. Red InP QD dispersed in octane was spin-coated on the hole transport layer to form a layer having a thickness of 20 nm, followed by baking at 100° C. for 10 minutes, thereby forming a red emission layer. Composition 1 was spin-coated on the red emission layer to form a layer having a thickness of 30 nm, followed by baking at 120° C. for 10 minutes, thereby forming an electron transport layer. After the glass substrate was mounted on a substrate holder of a vacuum deposition apparatus, AI was deposited on the electron transport layer to form an anode having a thickness of 100 nm, thereby completing the manufacture of a quantum dot light-emitting device. The deposition equipment used herein was a Suicel plus 200 evaporator manufactured by Sunic System Company.

### Examples 2-2 to 2-8 and Comparative Example 2-1

A device was manufactured in a similar manner as in Example 2-1, except that, in forming the electron transport layer, each composition described in Table 6 was used.

TABLE 6

| | |
|---|---|
| | ETL |
| Example 2-1 | Composition 1 |
| Example 2-2 | Composition 2 |
| Example 2-3 | Composition 3 |
| Example 2-4 | Composition 4 |
| Example 2-5 | Composition 5 |
| Example 2-6 | Composition 6 |
| Example 2-7 | Composition 7 |
| Example 2-8 | Composition 8 |
| Comparative Example 2-1 | Comparative Composition 2 |

### Evaluation Example 5

Driving voltage (Volts, V) at a current density of 10 milliamperes per square meter (mA/cm²), efficiency (candela per Ampere, cd/A), lifespan, and color purity (CIEx,y coordinates) of quantum dot light-emitting devices according to Examples 2-1 to 2-8 and Comparative Example 2-1 were measured by using the following methods, and results thereof are shown in Table 7 below. In Table 7 below, lifespan T90 represents the time (hr) taken for the luminance to reach 90% when the initial luminance (at 10 mA/cm²) is 100%.
Color coordinates: Power was supplied from a current-voltmeter (Keithley SMU 236), and color coordinates were measured using a luminance meter PR650.
Luminance: Power was supplied from a current-voltmeter (Keithley SMU 236), and luminance was measured using a luminance meter PR650.
Efficiency: Power was supplied from a current-voltmeter (Keithley SMU 236), and efficiency was measured using a luminance meter PR650.

TABLE 7

| | Driving voltage (V) | Efficiency (cd/A) | Color coordinates | | Lifespan T90 (hr) |
|---|---|---|---|---|---|
| | | | CIEx | ClEy | |
| Example 2-1 | 4.4 | 23.8 | 0.68 | 0.32 | 520 |
| Example 2-2 | 4.2 | 21.0 | 0.68 | 0.32 | 420 |
| Example 2-3 | 4.4 | 21.5 | 0.68 | 0.32 | 480 |
| Example 2-4 | 4.4 | 22.4 | 0.68 | 0.32 | 480 |
| Example 2-5 | 4.2 | 23.1 | 0.68 | 0.32 | 460 |
| Example 2-6 | 4.4 | 22.8 | 0.68 | 0.32 | 440 |
| Example 2-7 | 4.2 | 23.1 | 0.68 | 0.32 | 480 |
| Example 2-8 | 4.4 | 22.7 | 0.68 | 0.32 | 400 |
| Comparative Example 2-1 | 3.8 | 14.5 | 0.67 | 0.33 | 150 |

From Table 7, it was confirmed that the light-emitting devices according to Examples 2-1 to 2-8 had excellent efficiency and lifespan characteristics, as compared to the light-emitting device according to Comparative Example 2-1.

By using the solvent, the metal oxide is stably dispersed, a composition capable of an inkjet process is prepared, and a light-emitting device with improved luminescence characteristics may be manufactured by using the metal oxide composition.

It should be understood that the exemplary embodiments described herein should be considered in a descriptive sense and not for purposes of limitation. Descriptions of features or aspects within each exemplary embodiment should typically be considered as available for other similar features or aspects in other exemplary embodiments. While one or more exemplary embodiments have been described with reference to the figures, it will be understood by those of ordinary skill in the art that various changes in form and details may be made therein without departing from the spirit and scope as defined by the following claims.

What is claimed is:

1. A metal oxide composition, comprising:
a solvent; and
a metal oxide,
wherein the solvent comprises a first compound represented by Formula 1, and the metal oxide comprises a second compound represented by Formula 2: 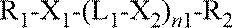 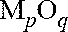
wherein, in Formulae 1 and 2,
L₁ is a single bond, a C₁-C₆₀ alkylene group that is unsubstituted or substituted with at least one R₁₀ₐ, a C₂-C₆₀ alkenylene group that is unsubstituted or substituted with at least one R₁₀ₐ, a C₂-C₆₀ alkynylene group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, or a combination thereof,
n1 is an integer from 1 to 10,
X₁ and X₂ are each independently *—B(R₁ₐ)—*’, *—N(R₁ₐ)—*’, *—O—*’, *—P(R₁ₐ)—*’, *—P(═O)(R₁ₐ)—*’, *—S—*’, *—S(═O)—*’, *—S(═O)₂—*’, or *—Si(R₁ₐ)(R_{1b})—*’,
* and *’ each indicate a binding site to a neighboring atom,
R₁ is hydrogen or deuterium,
R₂ is a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, or a C₁-C₆₀ heteroarylthio group that is unsubstituted or substituted with at least one R₁₀ₐ,
R₁ₐ and R_{1b} are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), —P(Q₁)(Q₂), or —P(═O)(Q₁)(Q₂),
M is Zn, Ti, Zr, Sn, W, Ta, Ni, Mo, Cu, or V, p and q are each independently from 1 to 5,
R₁₀ₐ is:
deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof;
a C₁-C₆₀ alkyl group, a C₂-C₆₀ alkenyl group, a C₂-C₆₀ alkynyl group, a C₁-C₆₀ alkoxy group, a C₁-C₆₀ alkylthio group, each unsubstituted or substituted with at least one of deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₆₀ carbocyclic group, a C₁-C₆₀ heterocyclic group, a C₇-C₆₀ alkyl aryl group, a C₇-C₆₀ aryl alkyl group, a C₆-C₆₀ aryloxy group, a C₆-C₆₀ arylthio group, a C₂-C₆₀ alkyl heteroaryl group, a C₂-C₆₀ heteroaryl alkyl group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(Q₁₁)(Q₁₂), —P(═O)(Q₁₁)(Q₁₂), or a combination thereof;
a C₃-C₆₀ carbocyclic group, a C₁-C₆₀ heterocyclic group, a C₇-C₆₀ alkyl aryl group, a C₇-C₆₀ aryl alkyl group, a C₆-C₆₀ aryloxy group, or a C₆-C₆₀ arylthio group, a C₂-C₆₀ alkyl heteroaryl group, a C₂-C₆₀ heteroaryl alkyl group, a C₁-C₆₀ heteroaryloxy group, a C₁-C₆₀ heteroarylthio group, each unsubstituted or substituted with at least one of deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₇-C₆₀ alkyl aryl group, a C₇-C₆₀ aryl alkyl group, a C₆-C₆₀ aryloxy group, a C₆-C₆₀ arylthio group, a C₂-C₆₀ alkyl heteroaryl group, a C₂-C₆₀ heteroaryl alkyl group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(Q₂₁)(Q₂₂), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(Q31)(Q32), or —P(═O)(Q31)(Q32),
Q₁ to Q₃, Q₁₁ to Q₁₃, Q₂₁ to Q₂₃, and Q₃₁ to Q₃₃ are each independently: hydrogen; deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₆₀ carbocyclic group, a substituted or unsubstituted C₁-C₆₀ heterocyclic group, a substituted or unsubstituted C₇-C₆₀ aryl alkyl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, and
the first compound satisfies at least one of Condition 1 or Condition 2:
Condition 1 at least one L₁ is substituted with at least one R₁₀ₐ
Condition 2 R₂ is substituted with at least one R₁₀ₐ.

2. The metal oxide composition of claim 1, wherein L₁ is a C₁-C₆₀ alkylene group that is unsubstituted or substituted with at least one R₁₀ₐ, a C₃-C₁₀ cycloalkylene group that is unsubstituted or substituted with at least one R₁₀ₐ, a C₃-C₁₀ heterocycloalkylene group that is unsubstituted or substituted with at least one R₁₀ₐ, a C₃-C₁₀ cycloalkenylene group that is unsubstituted or substituted with at least one R₁₀ₐ, or a C₁-C₁₀ heterocycloalkenylene group that is unsubstituted or substituted with at least one R₁₀ₐ.

3. The metal oxide composition of claim 1, wherein
X₁ and X₂ are each independently *—N(R₁ₐ)—*’, *—O—*’, *—S—*’, or *—Si(R₁ₐ)(R_{1b})—*’, * and *’ each indicate a binding site to a neighboring atom, and
R₁ₐ and R_{1b} are as described in claim 1.

4. The metal oxide composition of claim 1, wherein the first compound is represented by Formula 1-1 or 1-2 below: 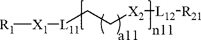 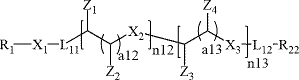
wherein, in Formulae 1-1 and 1-2,
L₁₁ and L₁₂ are each independently a single bond, a C₁-C₆₀ alkylene group that is unsubstituted or substituted with at least one R₁₀ₐ, a C₂-C₆₀ alkenylene group that is unsubstituted or substituted with at least one R₁₀ₐ, a C₂-C₆₀ alkynylene group that is unsubstituted or substituted with at least one R₁₀ₐ, a C₃-C₁₀ cycloalkylene group that is unsubstituted or substituted with at least one R₁₀ₐ, a C₃-C₁₀ heterocycloalkenylene group that is unsubstituted or substituted with at least one R₁₀ₐ, a C₃-C₁₀ cycloalkenylene group that is unsubstituted or substituted with at least one R₁₀ₐ, or a C₁-C₁₀ heterocycloalkenylene group that is unsubstituted or substituted with at least one R₁₀ₐ,
X₁ to X₃ are each independently *—B(R₁ₐ)—*’, *—N(R₁ₐ)—*’, *—O—*’, *—P(R₁ₐ)—*’, *—P(═O)(R₁ₐ)—*’, *—S—*’, *—S(═O)—*’, *—S(═O)₂—*’, or *—Si(R₁ₐ)(R_{1b})—*’, and * and *’ each indicate a binding site to a neighboring atom,
R₁ is hydrogen or deuterium,
R₂₁ is a C₃-C₂₀ alkyl group that is unsubstituted or substituted with at least one R₁₀ₐ, a C₃-C₂₀ alkenyl group that is unsubstituted or substituted with at least one R₁₀ₐ, a C₃-C₂₀ alkynyl group that is unsubstituted or substituted with at least one R₁₀ₐ, a C₁-C₂₀ alkoxy group that is unsubstituted or substituted with at least one R₁₀ₐ, a C₁-C₆₀ alkylthio group that is unsubstituted or substituted with at least one R₁₀ₐ, a C₃-C₃₀ carbocyclic group that is unsubstituted or substituted with at least one R₁₀ₐ, a C₁-C₃₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), —P(Q₁)(Q₂), or —P(═O)(Q₁)(Q₂),
R₂₂ is a C₁-C₂₀ alkyl group that is unsubstituted or substituted with at least one R₁₀ₐ, a C₂-C₂₀ alkenyl group that is unsubstituted or substituted with at least one R₁₀ₐ, a C₂-C₂₀ alkynyl group that is unsubstituted or substituted with at least one R₁₀ₐ, a C₁-C₂₀ alkoxy group that is unsubstituted or substituted with at least one R₁₀ₐ, a C₁-C₆₀ alkylthio group that is unsubstituted or substituted with at least one R₁₀ₐ, a C₃-C₃₀ carbocyclic group that is unsubstituted or substituted with at least one R₁₀ₐ, or a C₁-C₃₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ,
Z₁ to Z₄ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), —P(Q₁)(Q₂), or —P(═O)(Q₁)(Q₂),
at least one of Z₁ to Z₄ comprises at least one carbon atom,
n11 is an integer from 1 to 5,
n12 and n13 are each independently an integer from 0 to 5,
a sum of n12 and n13 is 1 or greater,
a11 to a13 are each independently an integer from 0 to 5, and
R₁₀ₐ, R₁ₐ, R_{1b}, and Q₁ to Q₃ are respectively as those described in claim 1.

5. The metal oxide composition of claim 4, wherein R₂₁ is:
a C₃-C₂₀ alkyl group that is unsubstituted or substituted with at least one of deuterium, —CD₃, —CD₂H, —CDH₂, —CF₃, —CF₂H, —CFH₂, a hydroxyl group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a tetrahydrofuranyl group, a pyrrolidinyl group, a piperidinyl group, a phenyl group, a biphenyl group, a naphthyl group, a pyridinyl group, a pyrimidinyl group, an indolinyl group, an isoindolinyl group, an isoindolyl group, an indolyl group, or a combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a tetrahydrofuranyl group, a tetrahydrothiophene group, a pyrrolidinyl group, a piperidinyl group, a phenyl group, a biphenyl group, a naphthyl group, a fluorenyl group, a phenanthrenyl group, an anthracenyl group, a fluoranthenyl group, a triphenylenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolinyl group, an isoindolinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, or a dibenzothiophenyl group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₁-C₂₀ alkylthio group, —Si(Q₃₁)(Q₃₂)(Q₃₃), —N(Q₃₁)(Q₃₂), or a combination thereof; or
— Si(Q₁)(Q₂)(Q₃) or —N(Q₁)(Q₂), and
Q₁ to Q₃ and Q₃₁ to Q₃₃ are each independently:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, or a naphthyl group, each unsubstituted or substituted with at least one of deuterium, a C₁-C₁₀ alkyl group, a phenyl group, or a combination thereof.

6. The metal oxide composition of claim 4, wherein R₂₂ is a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, or a tert-pentyl group.

7. The metal oxide composition of claim 4, wherein Z₁ to Z₄ are each independently:
hydrogen, deuterium, —F, —Cl, —Br, —I, —SF₅, a hydroxyl group, or a C₁-C₂₀ alkyl group that is unsubstituted or substituted with at least one R₁₀ₐ, or
each independently comprise *—(L₁₄—X₄)ₙ₁₄—*’,
wherein L₁₄ is a C₁-C₆₀ alkylene group that is unsubstituted or substituted with at least one R₁₀ₐ, a C₃-C₁₀ cycloalkylene group that is unsubstituted or substituted with at least one R₁₀ₐ, a C₃-C₁₀ heterocycloalkenylene group that is unsubstituted or substituted with at least one R₁₀ₐ, a C₃-C₁₀ cycloalkenylene group that is unsubstituted or substituted with at least one R₁₀ₐ, or a C₁-C₁₀ heterocycloalkenylene group that is unsubstituted or substituted with at least one R₁₀ₐ,
X₄ is *—B(R₁ₐ)—*’, *—N(R₁ₐ)—*’, *—O—*’, *—P(R₁ₐ)—*’, *—P(═O)(R₁ₐ)—*’, *—S—*’, *—S(═O)—*’, *—S(═O)₂—*’, or *—Si(R₁ₐ)(R_{1b})—*’,
n14 is an integer from 1 to 5,
* and *’ each indicate a binding site to a neighboring atom, and R₁ₐ, R_{1b}, and R₁₀ₐ are as described in claim 1.

8. The metal oxide composition of claim 4, wherein at least one of Z₁ to Z₄ is
a C₁-C₂₀ alkyl group that is unsubstituted or substituted with at least one R₁₀ₐ, or comprises *—(L₁₄—X₄)ₙ₁₄—*’,
wherein L₁₄ is a C₁-C₆₀ alkylene group that is unsubstituted or substituted with at least one R₁₀ₐ, a C₃-C₁₀ cycloalkylene group that is unsubstituted or substituted with at least one R₁₀ₐ, a C₃-C₁₀ heterocycloalkenylene group that is unsubstituted or substituted with at least one R₁₀ₐ, a C₃-C₁₀ cycloalkenylene group that is unsubstituted or substituted with at least one R₁₀ₐ, or a C₁-C₁₀ heterocycloalkenylene group that is unsubstituted or substituted with at least one R₁₀ₐ,
X₁₄ is *—N(R₁ₐ)—*’, *—O—*’, *—S—*’, or *—Si(R₁ₐ)(R_{1b})—*’,
n14 is an integer from 1 to 5,
* and *’ each indicate a binding site to a neighboring atom, and
R₁ₐ, R_{1b}, and R₁₀ₐ are as described in claim 1.

9. The metal oxide composition of claim 1, wherein the first compound is represented by Formula 1-1A, 1-1B, or 1-2A: 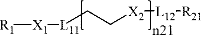 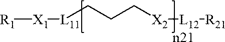 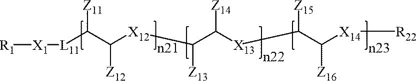 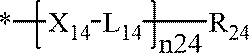
wherein, in Formulae 1-1 A, 1-1B, 1-2A, and 1-Z,
L₁₁, L₁₂, and L₁₄ are each independently a single bond, a C₁-C₆₀ alkylene group that is unsubstituted or substituted with at least one R₁₀ₐ, a C₂-C₆₀ alkenylene group that is unsubstituted or substituted with at least one R₁₀ₐ, a C₂-C₆₀alkynylene group that is unsubstituted or substituted with at least one R₁₀ₐ, a C₃-C₁₀ cycloalkylene group that is unsubstituted or substituted with at least one R₁₀ₐ, a C₃-C₁₀ heterocycloalkenylene group that is unsubstituted or substituted with at least one R₁₀ₐ, a C₃-C₁₀ cycloalkenylene group that is unsubstituted or substituted with at least one R₁₀ₐ, or a C₁-C₁₀ heterocycloalkenylene group that is unsubstituted or substituted with at least one R₁₀ₐ,
X₁, X₂, and X₁₂ to X₁₄ are each independently *—B(R₁ₐ)—*’, *—N(R₁ₐ)—*’, *—O—*’, *—P(R₁ₐ)—*’, *—P(═O)(R₁ₐ)—*’, *—S—*’, *—S(═O)—*’, *—S(═O)₂—*’, or *—Si(R₁ₐ)(R_{1b})—*’, and * and *’ each indicate a binding site to a neighboring atom,
R₁ is hydrogen or deuterium,
R₂₁ is a C₃-C₂₀ alkyl group that is unsubstituted or substituted with at least one R₁₀ₐ, a C₃-C₂₀ alkenyl group that is unsubstituted or substituted with at least one R₁₀ₐ, a C₃-C₂₀ alkynyl group that is unsubstituted or substituted with at least one R₁₀ₐ, a C₁-C₂₀ alkoxy group that is unsubstituted or substituted with at least one R₁₀ₐ, a C₁-C₆₀ alkylthio group that is unsubstituted or substituted with at least one R₁₀ₐ, a C₃-C₃₀ carbocyclic group that is unsubstituted or substituted with at least one R₁₀ₐ, a C₁-C₃₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ, —Si(Q₁)(Q₂)(Q₃), or —N(Q₁)(Q₂),
R₂₂ and R₂₄ are each independently a C₁-C₂₀ alkyl group that is unsubstituted or substituted with at least one R₁₀ₐ, a C₂-C₂₀ alkenyl group that is unsubstituted or substituted with at least one R₁₀ₐ, a C₂-C₂₀ alkynyl group that is unsubstituted or substituted with at least one R₁₀ₐ, a C₁-C₂₀ alkoxy group that is unsubstituted or substituted with at least one R₁₀ₐ, a C₁-C₆₀ alkylthio group that is unsubstituted or substituted with at least one R₁₀ₐ, a C₃-C₃₀ carbocyclic group that is unsubstituted or substituted with at least one R₁₀ₐ, a C₁-C₃₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, or a C₁-C₆₀ heteroarylthio group that is unsubstituted or substituted with at least one R₁₀ₐ,
Z₁₁ to Z₁₆ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₇-C₆₀ alkyl aryl group that is unsubstituted or substituted with at least one R₁₀ₐ, a C₇-C₆₀ aryl alkyl group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₁-C₆₀ alkyl heteroaryl group that is unsubstituted or substituted with at least one R₁₀ₐ, a C₂-C₆₀ heteroaryl alkyl group that is unsubstituted or substituted with at least one R₁₀ₐ, a C₁-C₆₀ heteroaryloxy group that is unsubstituted or substituted with at least one R₁₀ₐ, a C₁-C₆₀ heteroarylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
at least one of Z₁₁ to Z₁₆ is a C₁-C₆₀ alkyl group that is unsubstituted or substituted with at least one R₁₀ₐ, or comprises a group represented by Formula 1-Z,
n21 and n24 are each independently an integer from 1 to 5,
n22 and n23 are each independently an integer from 0 to 5, and
R₁ₐ, R_{1b}, R₁₀ₐ, and Q₁ to Q₃ are respectively as those described in claim 1.

10. The metal oxide composition of claim 1, wherein the first compound is one of Compounds 1 to 26 below: 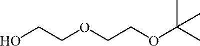 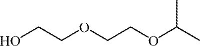 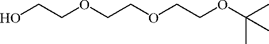 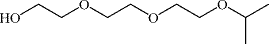 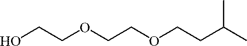 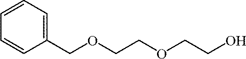 [SMILES: OCCOCCOCc1ccccc1] 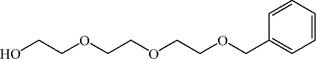 [SMILES: OCCOCCOCCOCc1ccccc1] 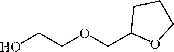 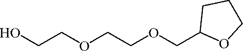 [SMILES: OCCOCCOCC1CCCO1] 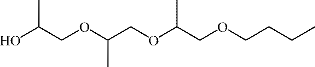 [SMILES: CCCCOCC(C)OCC(C)OCC(C)O] 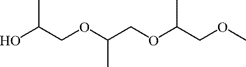 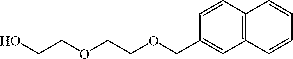 [SMILES: OCCOCCOCc1ccc2ccccc2c1] 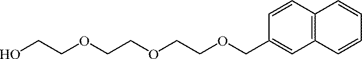 [SMILES: OCCOCCOCCOCc1ccc2ccccc2c1] 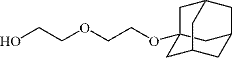 [SMILES: OCCOCCOC12CC3CC(CC(C3)C1)C2] 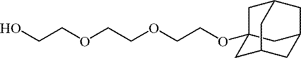 [SMILES: OCCOCCOCCOC12CC3CC(CC(C3)C1)C2] 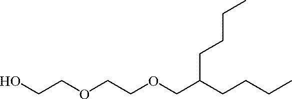 [SMILES: CCCCC(CCCC)COCCOCCO] 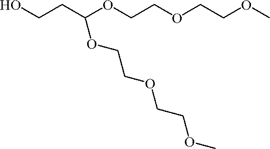 [SMILES: COCCOCCOC(CCO)OCCOCCOC] 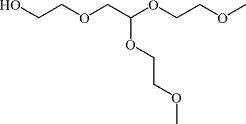 [SMILES: COCCOC(COCCO)OCCOC] 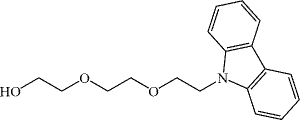 [SMILES: OCCOCCOCCn1c2ccccc2c2ccccc21] 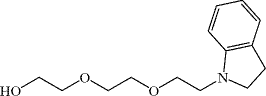 [SMILES: OCCOCCOCCN1CCc2ccccc21] 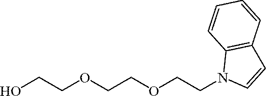 [SMILES: OCCOCCOCCn1ccc2ccccc21] 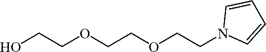 [SMILES: OCCOCCOCCn1cccc1] 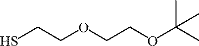 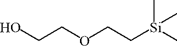 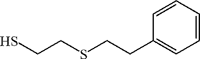 [SMILES: SCCSCCc1ccccc1] 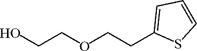 [SMILES: OCCOCCc1cccs1]
.

11. The metal oxide composition of claim 1, wherein the second compound is represented by Formula 2-1 below: 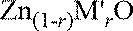
wherein, in Formula 2-1,
M′ is Mg, Co, Ni, Zr, Mn, Sn, Y, Al, or a combination thereof, and
r is a number greater than 0 and less than or equal to 0.5.

12. A light-emitting device comprising:
a first electrode;
a second electrode facing the first electrode;
an interlayer arranged between the first electrode and the second electrode,
wherein the interlayer comprises an emission layer; and
a metal oxide layer formed by using the metal oxide composition of claim 1.

13. The light-emitting device of claim 12, wherein the emission layer comprises a quantum dot.

14. The light-emitting device of claim 13, wherein the quantum dot comprises: a Group II-VI semiconductor compound; a Group III-V semiconductor compound; a Group III-VI semiconductor compound; a Group I-III-VI semiconductor compound; a Group IV-VI semiconductor compound; a Group IV element or compound; or a combination thereof.

15. The light-emitting device of claim 13, wherein the quantum dot comprises:
a core; and
a shell covering at least a portion of the core,
wherein the core comprises Cd, Zn, Hg, Mg, Ga, Al, In, Sn, Pb, Se, Te, P, S, or Sb.

16. The light-emitting device of claim 12, wherein
the first electrode is an anode,
the second electrode is a cathode,
the interlayer further comprises a hole transport region located between the first electrode and the emission layer, and an electron transport region located between the emission layer and the second electrode, and
the hole transport region or the electron transport region comprises the metal oxide layer.

17. The light-emitting device of claim 12, wherein the metal oxide layer is in direct contact with the emission layer.

18. An electronic apparatus, comprising the light-emitting device of claim 12.

19. The electronic apparatus of claim 18, further comprising a thin-film transistor,
wherein the thin-film transistor comprises a source electrode and a drain electrode, and
the first electrode of the light-emitting device is electrically connected to at least one of the source electrode and the drain electrode of the thin-film transistor.

20. The electronic apparatus of claim 19, further comprising a color filter, a color conversion layer, a touch screen layer, a polarizing layer, or a combination thereof.
